(19) United States
(12) Patent Application Publication
(10) Pub. No.: US 2021/0226063 A1
(43) Pub. Date: Jul. 22, 2021

(54) SEMICONDUCTOR DEVICE AND METHOD FOR MANUFACTURING SEMICONDUCTOR DEVICE

(71) Applicant: Semiconductor Energy Laboratory Co., Ltd., Atsugi-shi, Kanagawa-Ken (JP)

(72) Inventors: Shunpei YAMAZAKI, Setagaya (JP); Naoki OKUNO, Yamato (JP); Ryunosuke HONDA, Isehara (JP)

(21) Appl. No.: 17/264,503

(22) PCT Filed: Aug. 1, 2019
(86) PCT No.: PCT/IB2019/056553

§ 371 Date: Jan. 29, 2021

(30) Foreign Application Priority Data
Aug. 9, 2018 (JP) 2018-150490

(51) Int. Cl. H01L 29/786

(52) U.S. Cl. CPC H01L 29/7869; H01L 27/10805

(57) ABSTRACT

A semiconductor device that stably operates even at high temperature is provided. The semiconductor device includes a metal oxide, an insulating layer, a first conductive layer, a second conductive layer, and a third conductive layer. The metal oxide includes a first region, a second region, and a third region. The first region overlaps with the first conductive layer. The second region overlaps with the second conductive layer. The third region overlaps with the third conductive layer with the insulating layer interposed therebetween. The value of the ratio of the carrier concentration in the first region to the carrier concentration in the third region is 100 or more. The value of the ratio of the carrier concentration in the second region to the carrier concentration in the third region is 100 or more.

### TECHNICAL FIELD

One embodiment of the present invention relates to a semiconductor device and a method for manufacturing the semiconductor device. Another embodiment of the present invention relates to a semiconductor wafer, a module, and an electronic device.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

Note that one embodiment of the present invention is not limited to the above technical field. One embodiment of the invention disclosed in this specification and the like relates to an object, a method, or a manufacturing method. Another embodiment of the present invention relates to a process, a machine, manufacture, or a composition of matter.

### BACKGROUND ART

A technique for forming a transistor by using a semiconductor thin film formed over a substrate having an insulating surface has attracted attention. Such a transistor is widely used in electronic devices such as an integrated circuit (IC) and an image display device (also simply referred to as a display device). A silicon-based semiconductor material is widely known as a semiconductor thin film that can be used in a transistor, and as another material, an oxide semiconductor has attracted attention.

A CAAC (c-axis aligned crystalline) structure and an nc (nanocrystalline) structure, which are neither single crystal nor amorphous, have been found in an oxide semiconductor (see Non-Patent Document 1 and Non-Patent Document 2).

Non-Patent Document 1 and Non-Patent Document 2 disclose a technique for fabricating a transistor using an oxide semiconductor having a CAAC structure.

It is known that a transistor using an oxide semiconductor has an extremely low leakage current in a non-conduction state. For example, a CPU with low power consumption utilizing a characteristic of a low leakage current in a non-conduction state of a transistor using an oxide semiconductor is disclosed (see Patent Document 1).

### REFERENCES

### Patent Document

[Patent Document 1] Japanese Published Patent Application No. 2012-257187

### Non-Patent Documents

[Non-Patent Document 1] S. Yamazaki et al., “SID Symposium Digest of Technical Papers”, 2012, volume 43, issue 1, pp. 183-186.
[Non-Patent Document 2] S. Yamazaki et al., “Japanese Journal of Applied Physics”, 2014, volume 53, Number 4S, pp. 04ED18-1-04ED18-10.

### SUMMARY OF THE INVENTION

### Problems to be Solved by the Invention

A transistor using an oxide semiconductor has a higher off-state current and is more likely to have normally-on characteristics as the temperature during operation of the transistor increases. This is because, as the temperature during operation of the transistor increases, the threshold voltage of the transistor decreases and the subthreshold swing value (also referred to as S value) increases. Accordingly, particularly at high temperature, a semiconductor device including transistors has significant fluctuations in electrical characteristics, so that the reliability is highly likely reduced.

In view of the above, an object of one embodiment of the present invention is to provide a semiconductor device that stably operates even at high temperature. An object of one embodiment of the present invention is to provide a semiconductor device with a low off-state current. Another object of one embodiment of the present invention is to provide a highly reliable semiconductor device. Another object of one embodiment of the present invention is to provide a semiconductor device with a small variation. Another object of one embodiment of the present invention is to provide a semiconductor device with reduced power consumption.

Note that the description of these objects does not preclude the existence of other objects. Note that one embodiment of the present invention does not necessarily achieve all of these objects. Other objects will be apparent from the description of the specification, the drawings, the claims, and the like, and other objects can be derived from the description of the specification, the drawings, the claims, and the like.

### Means for Solving the Problems

One embodiment of the present invention is a semiconductor device including a metal oxide, an insulating layer, a first conductive layer, a second conductive layer, and a third conductive layer. The metal oxide includes a first region, a second region, and a third region. The first region overlaps with the first conductive layer. The second region overlaps with the second conductive layer. The third region overlaps with the third conductive layer with the insulating layer interposed therebetween. The carrier concentration in each of the first region and the second region is higher than or equal to 5×10¹⁷ cm⁻³ and lower than 1×10¹⁹ cm⁻³. The carrier concentration in the third region is higher than or equal to 1×10¹² cm⁻³ and lower than 5×10¹⁷ cm⁻³.

Another embodiment of the present invention is a semiconductor device including a metal oxide, an insulating layer, a first conductive layer, a second conductive layer, and a third conductive layer. The metal oxide includes a first region, a second region, and a third region. The first region overlaps with the first conductive layer. The second region overlaps with the second conductive layer. The third region overlaps with the third conductive layer with the insulating layer interposed therebetween. The value of the ratio of the carrier concentration in the first region to the carrier concentration in the third region is greater than or equal to 1×10². The value of the ratio of the carrier concentration in the second region to the carrier concentration in the third region is greater than or equal to 1×10².

Preferably in the above semiconductor device, a first layer is included between the first region and the first conductive layer, a second layer is included between the second region and the second conductive layer, the first conductive layer and the second conductive layer each include tantalum nitride, and the first layer and the second layer each include tantalum, nitrogen, and oxygen or include tantalum and oxygen.

Preferably in the above semiconductor device, the hydrogen concentration in the third region is lower than 1×10¹⁸ atoms/cm³.

Another embodiment of the present invention is a semiconductor device including a transistor. The transistor includes a metal oxide, a first insulating layer, a second insulating layer, a first conductive layer, a second conductive layer, a third conductive layer, and a fourth conductive layer. The second insulating layer is provided over the fourth conductive layer. The metal oxide is provided over the second insulating layer. The first insulating layer is provided over the metal oxide. The third conductive layer is provided over the first insulating layer. The first conductive layer is provided over the metal oxide. The second conductive layer is provided over the metal oxide. The third conductive layer overlaps with the fourth conductive layer with the metal oxide interposed therebetween. The off-state current of the transistor is lower than or equal to 1 aA at temperatures that range from 180° C. to 220° C.

Another embodiment of the present invention is a semiconductor device including a transistor. The transistor includes a metal oxide, a first insulating layer, a second insulating layer, a first conductive layer, a second conductive layer, a third conductive layer, and a fourth conductive layer. The second insulating layer is provided over the fourth conductive layer. The metal oxide is provided over the second insulating layer. The first insulating layer is provided over the metal oxide. The third conductive layer is provided over the first insulating layer. The first conductive layer is provided over the metal oxide. The second conductive layer is provided over the metal oxide. The third conductive layer overlaps with the fourth conductive layer with the metal oxide interposed therebetween. The off-state current per micrometer in the channel width of the transistor is lower than or equal to 10 aA/μm at temperatures that range from 180° C. to 220° C.

In the above semiconductor device, the metal oxide preferably contains indium, an element M (M is aluminum, gallium, yttrium, or tin), and zinc.

### Effect of the Invention

According to one embodiment of the present invention, a semiconductor device that stably operates even at high temperature can be provided. According to one embodiment of the present invention, a semiconductor device with low off-state current can be provided. According to one embodiment of the present invention, a highly reliable semiconductor device can be provided. According to one embodiment of the present invention, a semiconductor device with a small variation can be provided. According to one embodiment of the present invention, a semiconductor device with reduced power consumption can be provided.

Note that the description of these effects does not preclude the existence of other effects. Note that one embodiment of the present invention does not necessarily have all of these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A and FIG. 1B are schematic cross-sectional views of semiconductor devices which are one embodiment of the present invention.

FIG. 2A is a top view of a transistor assumed in calculation using a device simulator.

FIG. 2B and FIG. 2C are cross-sectional views of the transistor assumed in calculation using the device simulator.

FIG. 3 shows calculation results of Id-Vg characteristics of transistors.

FIG. 4A to FIG. 4D are schematic cross-sectional views of semiconductor devices which are one embodiment of the present invention.

FIG. 5A and FIG. 5B show drain currents of a transistor.

FIG. 6A is a top view illustrating a structure example of a transistor of one embodiment of the present invention. FIG. 6B and FIG. 6C are cross-sectional views illustrating a structure example of the transistor of one embodiment of the present invention.

FIG. 7A is a top view illustrating a structure example of a transistor of one embodiment of the present invention. FIG. 7B and FIG. 7C are cross-sectional views illustrating a structure example of the transistor of one embodiment of the present invention.

FIG. 8A is a top view illustrating a structure example of a transistor of one embodiment of the present invention. FIG. 8B and FIG. 8C are cross-sectional views illustrating a structure example of the transistor of one embodiment of the present invention.

FIG. 9A is a top view illustrating a structure example of a transistor of one embodiment of the present invention. FIG. 9B and FIG. 9C are cross-sectional views illustrating a structure example of the transistor of one embodiment of the present invention.

FIG. 10A and FIG. 10B are block diagrams illustrating a structure example of a memory device of one embodiment of the present invention.

FIG. 11A to FIG. 11H are circuit diagrams illustrating structure examples of a memory device of one embodiment of the present invention.

FIG. 12A and FIG. 12B are schematic views of a semiconductor device of one embodiment of the present invention.

FIG. 13A is a block diagram of a display device. FIG. 13B and FIG. 13C are circuit diagrams of the display device.

FIG. 14A to FIG. 14C are circuit diagrams of a display device.

FIG. 15A is a circuit diagram of a display device. FIG. 15B is a timing chart. FIG. 15C and FIG. 15D are circuit diagrams of the display device.

FIG. 16A to FIG. 16D are views illustrating electronic devices of one embodiment of the present invention.

FIG. 17A to FIG. 17H are views illustrating electronic devices of one embodiment of the present invention.

FIG. 18A and FIG. 18B show hydrogen concentration and carrier concentration in metal oxide films of this example.

FIG. 19A and FIG. 19B show hydrogen concentration and carrier concentration in metal oxide films of this example.

### MODE FOR CARRYING OUT THE INVENTION

Hereinafter, embodiments will be described with reference to the drawings. Note that the embodiments can be implemented with many different modes, and it will be readily appreciated by those skilled in the art that modes and details thereof can be changed in various ways without departing from the spirit and scope thereof. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. Note that the drawings schematically illustrate ideal examples, and embodiments of the present invention are not limited to shapes, values, or the like shown in the drawings. For example, in the actual manufacturing process, a layer, a resist mask, or the like might be unintentionally reduced in size by treatment such as etching, which is not reflected in the drawings in some cases for easy understanding. Note that in the drawings, the same reference numerals are used, in different drawings, for the same portions or portions having similar functions, and repeated description thereof is omitted in some cases. Furthermore, the same hatch pattern is used for the portions having similar functions, and the portions are not especially denoted by reference numerals in some cases.

Furthermore, especially in a top view (also referred to as a “plan view”), a perspective view, or the like, the description of some components might be omitted for easy understanding of the invention. Furthermore, the description of some hidden lines and the like might be omitted.

In this specification and the like, the ordinal numbers such as first and second are used for convenience and do not denote the order of steps or the stacking order of layers. Therefore, for example, description can be made when “first” is replaced with “second”, “third”, or the like, as appropriate. In addition, the ordinal numbers in this specification and the like do not correspond to the ordinal numbers which are used to specify one embodiment of the present invention in some cases.

In this specification and the like, terms for describing arrangement, such as “over” and “under”, are used for convenience in describing a positional relationship between components with reference to drawings. Furthermore, the positional relationship between components is changed as appropriate in accordance with a direction in which each component is described. Thus, without limitation to terms described in this specification, the description can be changed appropriately depending on the situation.

In the case where there is an explicit description, X and Y are connected, in this specification and the like, for example, the case where X and Y are electrically connected, the case where X and Y are functionally connected, and the case where X and Y are directly connected are disclosed in this specification and the like. Accordingly, without being limited to a predetermined connection relationship, for example, a connection relationship shown in drawings or texts, a connection relationship other than one shown in drawings or texts is disclosed in the drawings or the texts. Here, X and Y each denote an object (e.g., a device, an element, a circuit, a wiring, an electrode, a terminal, a conductive film, or a layer).

In this specification and the like, a transistor is an element having at least three terminals of a gate, a drain, and a source. In addition, the transistor includes a region where a channel is formed (hereinafter, also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Functions of a source and a drain might be switched when a transistor of opposite polarity is employed or a direction of current is changed in circuit operation. Therefore, the terms “source” and “drain” can be interchanged with each other in this specification and the like in some cases.

Note that a channel length refers to, for example, a distance between a source (a source region or a source electrode) and a drain (a drain region or a drain electrode) in a region where a semiconductor (or a portion where current flows in a semiconductor when a transistor is in an on state) and a gate electrode overlap with each other or a channel formation region in a top view of the transistor. Note that in one transistor, channel lengths in all regions are not necessarily the same. In other words, the channel length of one transistor is not fixed to one value in some cases. Thus, in this specification, the channel length is any one of the values, the maximum value, the minimum value, or the average value in a channel formation region.

A channel width refers to, for example, a length of a channel formation region in a direction perpendicular to a channel length direction in a region where a semiconductor (or a portion where current flows in a semiconductor when a transistor is in an on state) and a gate electrode overlap with each other, or a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, or the average value in a channel formation region.

Note that in this specification and the like, depending on transistor structures, a channel width in a region where a channel is actually formed (hereinafter, also referred to as an “effective channel width”) is different from a channel width shown in a top view of a transistor (hereinafter, also referred to as an “apparent channel width”) in some cases. For example, when a gate electrode covers a side surface of a semiconductor, an effective channel width is greater than an apparent channel width, and its influence cannot be ignored in some cases. For example, in a miniaturized transistor having a gate electrode covering a side surface of a semiconductor, the proportion of a channel formation region formed in the side surface of the semiconductor is increased in some cases. In that case, an effective channel width is greater than an apparent channel width.

In such a case, an effective channel width is difficult to estimate by actual measurement in some cases. For example, estimation of an effective channel width from a design value requires an assumption that the shape of a semiconductor is known. Accordingly, in the case where the shape of a semiconductor is not known accurately, it is difficult to measure an effective channel width accurately.

In this specification, the simple term “channel width” refers to an apparent channel width in some cases. Alternatively, in this specification, the simple term “channel width” refers to an effective channel width in some cases. Note that values of a channel length, a channel width, an effective channel width, an apparent channel width, and the like can be determined, for example, by analyzing a cross-sectional TEM image and the like.

Note that an impurity in a semiconductor refers to, for example, elements other than the main components of the semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. In the case of an oxide semiconductor, water also serves as an impurity in some cases. Also in the case of an oxide semiconductor, oxygen vacancies are formed in some cases by entry of impurities, for example. Furthermore, when the semiconductor is silicon, examples of an impurity that changes characteristics of the semiconductor include oxygen, Group 1 elements except hydrogen, Group 2 elements, Group 13 elements, and Group 15 elements.

Note that in this specification and the like, silicon oxynitride is a material that contains more oxygen than nitrogen in its composition. Moreover, silicon nitride oxide is a material that contains more nitrogen than oxygen in its composition.

In addition, in this specification and the like, the term “insulating layer” can be replaced with an insulating film or an insulating layer. Moreover, the term “conductor” can be replaced with a conductive film or a conductive layer. Furthermore, the term “semiconductor” can be replaced with a semiconductor film or a semiconductor layer.

In this specification and the like, “parallel” indicates a state where two straight lines are placed at an angle of greater than or equal to −10° and less than or equal to 10°. Thus, the case where the angle is greater than or equal to −5° and less than or equal to 5° is also included. In addition, the term “substantially parallel” indicates a state where two straight lines are placed at an angle greater than or equal to −30° and less than or equal to 30°. Moreover, “perpendicular” indicates a state where two straight lines are placed at an angle of greater than or equal to 80° and less than or equal to 100°. Thus, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a metal oxide is an oxide of metal in a broad sense. Metal oxides are classified into an oxide insulating layer, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor.

In this specification and the like, “normally off” means that the drain current (also referred to as off-state current) per micrometer in the channel width flowing through a transistor when no potential is applied to a gate or the gate is supplied with a ground potential is 1×10⁻²⁰ A or lower at room temperature, 1×10⁻¹⁸ A or lower at 85° C., or 1×10⁻¹⁶ A or lower at 125° C.

### Embodiment 1

In this embodiment, an example of a transistor of one embodiment of the present invention is described.

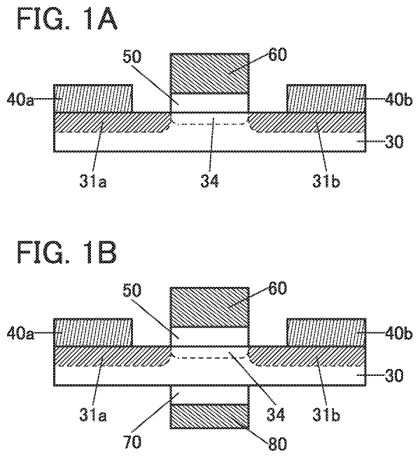

FIG. 1A and FIG. 1B show schematic cross-sectional views of a transistor 10 of one embodiment of the present invention. FIG. 1A and FIG. 1B are cross-sectional views of the transistor 10 in the channel length direction.

As illustrated in FIG. 1A, the transistor 10 includes a semiconductor layer 30 placed over a substrate (not illustrated), a conductive layer 40a, a conductive layer 40b, and an insulating layer 50 which are placed over the semiconductor layer 30, and a conductive layer 60 placed over the insulating layer 50. The semiconductor layer 30 includes a region 34, a region 31a, and a region 31b.

At least part of the conductive layer 60 overlaps with the region 34 of the semiconductor layer 30 with the insulating layer 50 interposed therebetween. At least part of the conductive layer 40a overlaps with the region 31a of the semiconductor layer 30, and at least part of the conductive layer 40b overlaps with the region 31b of the semiconductor layer 30.

The conductive layer 60 functions as a gate electrode of the transistor 10, the insulating layer 50 functions as a gate insulating layer of the transistor 10, the conductive layer 40a functions as one of a source electrode and a drain electrode of the transistor 10, and the conductive layer 40b functions as the other of the source electrode and the drain electrode of the transistor 10. The region 34 of the semiconductor layer 30 functions as a channel formation region of the transistor 10, the region 31a of the semiconductor layer 30 functions as one of a source region and a drain region of the transistor 10, and the region 31b of the semiconductor layer 30 functions as the other of the source region and the drain region of the transistor 10.

The transistor 10 may include an insulating layer 70 placed under the semiconductor layer 30 and a conductive layer 80 placed under the insulating layer 70, as illustrated in FIG. 1B. At least part of the conductive layer 80 overlaps with the region 34 of the semiconductor layer 30 with the insulating layer 70 interposed therebetween. In this case, the conductive layer 60 functions as a first gate electrode of the transistor 10, the insulating layer 50 functions as a first gate insulating layer of the transistor 10, the conductive layer 80 functions as a second gate electrode of the transistor 10, and the insulating layer 70 functions as a second gate insulating layer of the transistor 10.

Note that in FIG. 1B, the region 34 of the semiconductor layer 30 is formed in a top surface (the conductive layer 60 side) of the semiconductor layer 30; however, this embodiment is not limited thereto. For example, the region 34 of the semiconductor layer 30 may be formed in a bottom surface (the conductive layer 80 side) of the semiconductor layer 30, or may be formed from the top surface to the bottom surface of the semiconductor layer 30.

A metal oxide functioning as a semiconductor (hereinafter, also referred to as an oxide semiconductor) is preferably used in a channel formation region of a transistor. When an oxide semiconductor is used in a channel formation region of a transistor, a transistor having high field-effect mobility can be achieved. In addition, a transistor having high reliability can be achieved.

The transistor using an oxide semiconductor in a channel formation region has an extremely low leakage current in a non-conduction state; thus, a semiconductor device with low power consumption can be provided. An oxide semiconductor can be deposited by a sputtering method or the like, and thus can be used for a transistor included in a highly integrated semiconductor device.

For example, as the oxide semiconductor, a metal oxide such as an In-M-Zn oxide (an element M is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like) is preferably used. In particular, aluminum, gallium, yttrium, or tin is preferably used as the element M. Furthermore, an In-M oxide, an In—Zn oxide, or an M-Zn oxide may be used as the oxide semiconductor.

When a metal oxide is used for the channel formation region of a transistor, hydrogen in the metal oxide is preferably reduced as much as possible. In particular, hydrogen contained in a metal oxide reacts with oxygen bonded to a metal atom to be water, and thus forms oxygen vacancies in the metal oxide in some cases. When the channel formation region of the metal oxide includes oxygen vacancies, the transistor has normally-on characteristics in some cases. Moreover, a defect that is an oxygen vacancy into which hydrogen enters functions as a donor and generates electrons serving as carriers in some cases. Furthermore, bonding of part of hydrogen to oxygen bonded to a metal atom causes generation of an electron serving as a carrier in some cases. Thus, a transistor using a metal oxide including hydrogen is likely to have normally-on characteristics.

A defect in which hydrogen has entered an oxygen vacancy can function as a donor of the oxide semiconductor. However, it is difficult to evaluate the defects quantitatively. Thus, the oxide semiconductor is sometimes evaluated by not its donor concentration but its carrier concentration. Therefore, in this specification and the like, the carrier concentration assuming the state where an electric field is not applied is sometimes used, instead of the donor concentration, as the parameter of the oxide semiconductor. That is, “carrier concentration” in this specification and the like can be replaced with “donor concentration” in some cases.

As described above, as the temperature during operation of a transistor using an oxide semiconductor increases, the threshold voltage of the transistor decreases and the subthreshold swing value increases. Moreover, the threshold voltage and subthreshold swing value of the transistor correlate with the carrier concentration in the oxide semiconductor.

In view of the above, in the case where the oxide semiconductor is used in the channel formation region of a transistor, an i-type (intrinsic) or substantially i-type oxide semiconductor with a low carrier concentration is preferably used. When the oxide semiconductor with a low carrier concentration is used in the channel formation region of a transistor, the off-state current of the transistor can be kept low or the reliability of the transistor can be improved.

Here, a change in electrical characteristics of a transistor with changing donor concentration in a channel formation region of the transistor is described. Specifically, the Id-Vg characteristics of a transistor with changing donor concentration in a semiconductor layer included in the transistor were calculated with a device simulator.

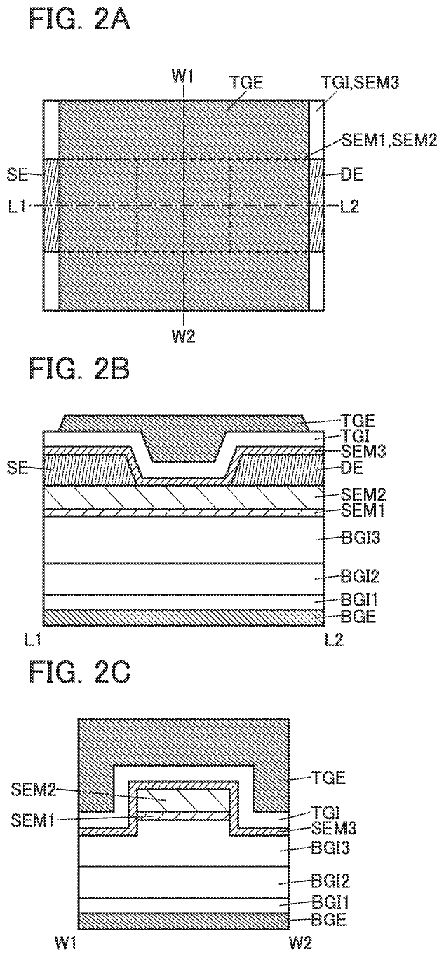

FIG. 2A to FIG. 2C show a top view and cross-sectional views of the transistor assumed in the calculation used for the device simulator. FIG. 2A is a top view of the transistor. FIG. 2B is a cross-sectional view of a portion indicated by the dashed-dotted line L1-L2 in FIG. 2A, and is also a cross-sectional view of the transistor in the channel length direction. FIG. 2C is a cross-sectional view of a portion indicated by the dashed-dotted line W1-W2 in FIG. 2A, and is also a cross-sectional view of the transistor in the channel width direction. Note that for clarity of the drawing, some components are omitted in the top view of FIG. 2A.

As shown in FIG. 2A to FIG. 2C, the transistor includes a conductive layer BGE placed over a substrate (not illustrated), an insulating layer BGI1, an insulating layer BGI2, and an insulating layer BGI3 placed over the conductive layer BGE, a semiconductor layer SEM1 and a semiconductor layer SEM2 placed over the insulating layer BGI3, a conductive layer SE and a conductive layer DE placed over the semiconductor layer SEM2, a semiconductor layer SEM3 placed over the semiconductor layer SEM2, the conductive layer SE, and the conductive layer DE, an insulating layer TGI placed over the semiconductor layer SEM3, and a conductive layer TGE placed over the insulating layer TGI.

The conductive layer TGE functions as a first gate (also referred to as a top gate). The conductive layer BGE functions as a second gate (also referred to as a back gate). The insulating layer TGI functions as a first gate insulating layer (also referred to as a top gate insulating layer). The insulating layer BGI1, the insulating layer BGI2, and the insulating layer BGI3 function as second gate insulating layers (also referred to as back gate insulating layers). The semiconductor layer SEM1, the semiconductor layer SEM2, and the semiconductor layer SEM3 function as semiconductor layers. The conductive layer SE functions as a source. The conductive layer DE functions as a drain.

The conductive layer TGE corresponds to the conductive layer 60 of the transistor 10 illustrated in FIG. 1B. The insulating layer TGI corresponds to the insulating layer 50 of the transistor 10 illustrated in FIG. 1B. The semiconductor layer SEM1 and the semiconductor layer SEM2 correspond to the semiconductor layer 30 of the transistor 10 illustrated in FIG. 1B. The conductive layer SE corresponds to the conductive layer 40a of the transistor 10 illustrated in FIG. 1B. The conductive layer DE corresponds to the conductive layer 40b of the transistor 10 illustrated in FIG. 1B. Furthermore, the conductive layer BGE corresponds to the conductive layer 80 of the transistor 10 illustrated in FIG. 1B. The insulating layer BGI1, the insulating layer BGI2, and the insulating BGI3 correspond to the insulating layer 70 of the transistor 10 illustrated in FIG. 1B.

The transistor shown in FIG. 2A to FIG. 2C includes the top gate and the back gate. Applying different potentials to the top gate and the back gate can adjust the threshold voltage of the transistor including the top gate and the back gate. For example, applying a negative potential to the back gate can increase the threshold voltage of the transistor, which can reduce the off-state current. In other words, the drain current at the time when the potential applied to the top gate is 0 V can be reduced by applying a negative potential to the back gate.

In this calculation, structures (Structure 1A to Structure 7A) that differ in the donor concentration in the semiconductor layer SEM1 and the semiconductor layer SEM2 were prepared. Table 1 shows the values of the parameters different among Structure 1A to Structure 7A, which are included in the parameters assumed in the calculation using the device simulator.

TABLE 1

| | Donor concentration [cm⁻³] in |
|---|---|
| | semiconductor layer SEM1 |
| Structure | and semiconducto layer SEM2 |
| 1A | 1 × 10¹² |
| 2A | 1 × 10¹³ |
| 3A | 2 × 10¹⁶ |
| 4A | 2 × 10¹⁷ |
| 5A | 5 × 10¹⁷ |
| 6A | 1 × 10¹⁸ |
| 7A | 1 × 10¹⁹ |

Electrical characteristics of Structure 1A to Structure 7A were calculated by the calculation of each structure using the device simulator. A device simulator Atlas 3D produced by Silvaco, Inc. was used as the device simulator. Table 2 shows the values of the parameters common to Structure 1A to Structure 7A, which are included in the parameters assumed in the calculation using the device simulator.

TABLE 2

| | | | | |
|---|---|---|---|---|
| Structure | Channel length L | | 60 | nm |
| | Channel width W | | 60 | nm |
| SEM1 | IGZO(134) | Electron affinity | 4.5 | eV |
| | | Band gap | 3.4 | eV |
| | | Electron mobility | 0.1 | cm²/(V·s) |
| | | Hole mobility | 0.01 | cm²/(V·s) |
| | | Thickness | 5 | nm |
| SEM2 | IGZO(423) | Electron affinity | 4.8 | eV |
| SEM3 | | Band gap | 2.9 | eV |
| | | Electron mobility | 15 | cm²/(V·s) |
| | | Hole mobility | 0.01 | cm²/(V·s) |
| | | Thickness (SEM2) | 15 | nm |
| | | Thickness (SEM3) | 5 | nm |

| | | | |
|---|---|---|---|
| SEM | Dielectric constant | 15 | |
| | Effective density of states in | 5 × 10¹⁸ | cm⁻³ |
| | conduction band Nc | | |
| | Effective density of states in | 5 × 10¹⁸ | cm⁻³ |
| | valence band Nv | | |
| TGE | Work function | 5.9 | eV |
| | Thickness | 20 | nm |
| TGI | Dielectric constant | 4.1 | |
| | Thickness | 10 | nm |
| SE, DE | Work function | 4.8 | eV |
| | Thickness | 20 | nm |
| BGI3 | Dielectric constant | 4.1 | |
| | Thickness | 30 | nm |
| BGI2 | Dielectric constant | 16.4 | nm |
| | Thickness | 20 | |
| BGI1 | Dielectric constant | 4.1 | nm |
| | Thickness | 10 | |
| BGE | Work function | 5.0 | eV |
| | Thickness | 20 | nm |

Specifically, the Id-Vg characteristics of Structure 1A to Structure 7A at drain voltage Vd=1.2 V were calculated. Note that in this calculation, a potential was not applied to the back gate.

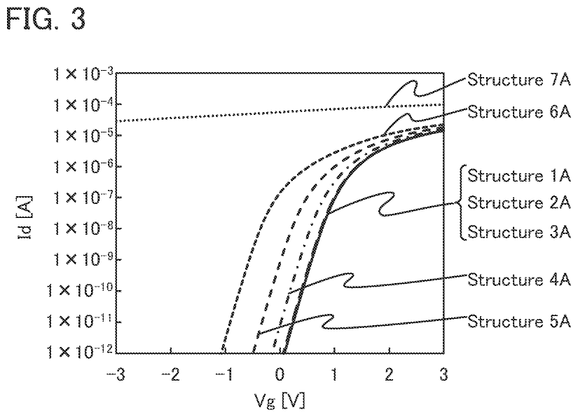

FIG. 3 shows the Id-Vg characteristics of Structure 1A to Structure 7A obtained by the calculation. In FIG. 3, the horizontal axis represents a change in gate voltage Vg [V] and the vertical axis represents a change in drain current Id [A]. Note that FIG. 3 is a semi-log graph with a logarithmic vertical axis.

According to FIG. 3, transistor characteristics of Structure 1A to Structure 6A were obtained. In other words, it is found that the transistor characteristics can be obtained when the donor concentration in the semiconductor layer SEM1 and the semiconductor layer SEM2 is set to 1×10¹⁸ cm⁻³ or lower. Furthermore, the lower the donor concentration in the semiconductor layer SEM1 and the semiconductor layer SEM2 is, the more the threshold voltage tends to be shifted in the positive direction. This indicates that the donor concentration in the semiconductor layer SEM2 is preferably low so that the transistor can be a normally-off transistor having stable electrical characteristics. In addition, the Id-Vg characteristics of Structure 1A to Structure 3A are substantially the same.

As described above, the carrier concentration in the region 34 of the semiconductor layer 30 which functions as the channel formation region of the transistor 10 is preferably lower than or equal to 1×10¹⁸ cm⁻³, further preferably lower than 5×10¹⁷ cm⁻³, still further preferably lower than 2×10¹⁷ cm⁻³, still further preferably lower than 2×10¹⁶ cm⁻³. In addition, the carrier concentration in the region 34 of the semiconductor layer 30 is preferably higher than or equal to 1×10¹² cm⁻³, further preferably higher than or equal to 1×10¹³ cm⁻³. Such a structure enables the threshold voltage of the transistor 10 to be increased and the subthreshold swing value to be lowered regardless of the temperature during operation of the transistor. Consequently, the off-state current of the transistor 10 can be reduced, and the reliability of the transistor 10 can be increased.

As described above, a transistor using a metal oxide including hydrogen is likely to have normally-on characteristics. Thus, hydrogen in the metal oxide is preferably reduced as much as possible. Specifically, the hydrogen concentration in the region 34 of the semiconductor layer 30, which is measured by secondary ion mass spectrometry (SIMS), is lower than 1×10²⁰ atoms/cm³, preferably lower than 1×10¹⁹ atoms/cm³, more preferably lower than 5×10¹⁸ atoms/cm³, still more preferably lower than 1×10¹⁸ atoms/cm³, still further preferably lower than 2×10¹⁷ atoms/cm³. When a metal oxide in which hydrogen is sufficiently reduced is used in the channel formation region of a transistor, stable electrical characteristics can be given. Note that the relationship between hydrogen concentration and carrier concentration in a metal oxide is described later.

The region 31a and the region 31b of the semiconductor layer 30 preferably include low-resistance regions. The region 31a which includes a low-resistance region and is provided between the conductive layer 40a and the region 34 weakens an electric field of a junction portion between the conductive layer 40a and the region 34 to inhibit hot-carrier degradation, so that the reliability can be improved. The region 31b including a low-resistance region provided between the conductive layer 40b and the region 34 weakens an electric field of a junction portion between the conductive layer 40b and the region 34 to inhibit hot-carrier degradation, so that the reliability can be improved.

A junction between the semiconductor layer 30 and the conductive layer 40a and a junction between the semiconductor layer 30 and the conductive layer 40b become Schottky contacts in many cases. When the semiconductor layer 30 and the conductive layer 40b form a Schottky contact, the low-resistance regions included in the region 31a and the region 31b can lower Schottky barriers between the semiconductor layer 30 and the conductive layer 40a and between the semiconductor layer 30 and the conductive layer 40b, so that contact resistance can be reduced. Although the junction between the semiconductor layer 30 and the conductive layer 40a is preferably a Schottky contact as described above, one embodiment of the present invention is not limited to this. For example, the junction between the semiconductor layer 30 and the conductive layer 40a may be an ohmic contact as long as the transistor characteristics are obtained. Although only the junction between the semiconductor layer 30 and the conductive layer 40a is mentioned above, the junction between the semiconductor layer 30 and the conductive layer 40b may also be an ohmic contact.

For example, the carrier concentration in the low-resistance regions included in the region 31a and the region 31b of the semiconductor layer 30 is preferably higher than or equal to 1×10¹⁷ cm⁻³ and lower than 1×10²¹ cm⁻³, further preferably higher than or equal to 5×10¹⁷ cm⁻³ and lower than 1×10¹⁹ cm⁻³.

Note that the carrier concentration in the low-resistance regions included in the region 31a and the region 31b of the semiconductor layer 30 is preferably higher than the carrier concentration in the region 34 of the semiconductor layer 30 which functions as the channel formation region of the transistor 10. For example, the values of the ratio of the carrier concentration in the region 31a and the region 31b of the semiconductor layer 30 to the carrier concentration in the region 34 of the semiconductor layer 30 are each preferably higher than or equal to 10, further preferably higher than or equal to 1×10², still further preferably higher than or equal to 2×10³ and lower than or equal to 2×10⁵. Thus, the drain current flowing when the transistor 10 is in a conduction state (on-state current) can be increased.

Although the region 34, the region 31a, and the region 31b of the semiconductor layer 30 are formed in the top surface (the side of the conductive layer 60, the conductive layer 40a, and the conductive layer 40b) of the semiconductor layer 30 in FIG. 1A, this embodiment is not limited to this. The region 34, the region 31a, and the region 31b of the semiconductor layer 30 may be formed from the top surface to the bottom surface of the semiconductor layer 30, for example.

Although the boundary between the region 34 and the region 31a and the boundary between the region 34 and the region 31b are substantially aligned with the side surfaces of the conductive layer 60 and the insulating layer 50 in FIG. 1A, this embodiment is not limited to this.

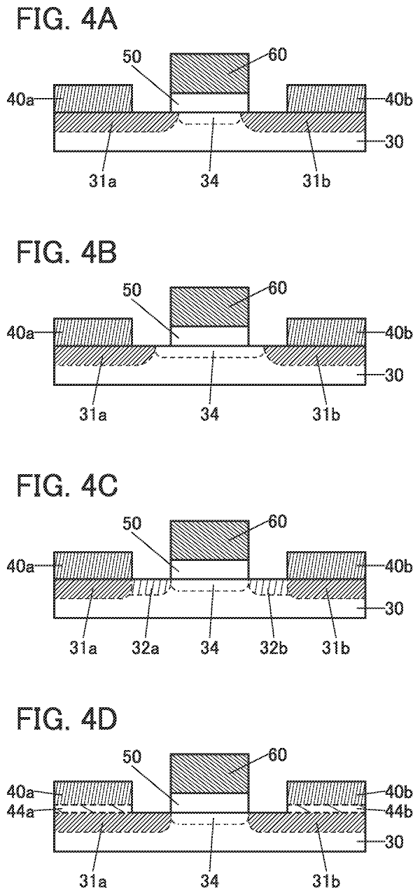

For example, as illustrated in FIG. 4A, the region 31a and the region 31b may each have a region overlapping with the conductive layer 60 with the insulating layer 50 interposed therebetween. In such a structure, a high-resistance region is not formed between the channel formation region and the source region or drain region of the semiconductor layer 30, whereby the on-state current and mobility of the transistor 10 can be increased.

For example, as illustrated in FIG. 4B, the boundary between the region 34 and the region 31a and the boundary between the region 34 and the region 31b may be positioned in a region where the semiconductor layer 30, the conductive layer 60, the conductive layer 40a, and the conductive layer 40b do not overlap with each other. Such a structure can reduce the off-state current of the transistor 10.

As illustrated in FIG. 4C, the semiconductor layer 30 may include a region 32a between the region 34 and the region 31a and a region 32b between the region 34 and the region 31b. The carrier concentration in the region 32a is preferably higher than the carrier concentration in the region 34 and lower than the carrier concentration in the region 31a. Similarly, the carrier concentration in the region 32b is preferably higher than the carrier concentration in the region 34 and lower than the carrier concentration in the region 31b. With such a structure, a difference in carrier concentration between the region 31a and the region 34 and a difference in carrier concentration between the region 31b and the region 34 can be reduced, and the on-state current and mobility of the transistor 10 can be increased. In addition, a short-channel effect can be inhibited.

In the case where a metal oxide is used for the semiconductor layer 30, the conductive layer 40 (the conductive layer 40a and the conductive layer 40b) might be in contact with the semiconductor layer 30, so that the conductive layer 40 might be oxidized with an oxygen atom forming the metal oxide of the semiconductor layer 30. The oxidation of the conductive layer 40 decreases the conductivity of the conductive layer 40. When the oxygen atom in the semiconductor layer 30 diffuses to the conductive layer 40, the semiconductor layer 30 in the vicinity of the interface with the conductive layer 40 is brought into an oxygen-deficient state. These are likely to cause fluctuations in electrical characteristics of the transistor and a reduction in reliability of the transistor, for example.

By the oxidation of the conductive layer 40, a layer 44a (a layer 44b) is formed between the conductive layer 40a (conductive layer 40b) and the semiconductor layer 30 in some cases, as illustrated in FIG. 4D. In the case where the layer 44a and the layer 44b have insulating properties, the three-layer structure of the conductive layer 40a (conductive layer 40b), the layer 44a (layer 44b), and the semiconductor layer 30 is a three-layer structure formed of metal-insulator-semiconductor, which is referred to as an MIS (Metal-Insulator-Semiconductor) structure in some cases. When the three-layer structure is included, there is a strong possibility that the transfer of carriers between the conductive layer 40a (conductive layer 40b) and the semiconductor layer 30 be inhibited. The formation of the layer 44a and the layer 44b can inhibit the interface between the conductive layer 40a (conductive layer 40b) and the semiconductor layer 30 from being degraded by the heat treatment.

For example, when a tantalum nitride film is used for the conductive layer 40 and a metal oxide is used for the semiconductor layer 30, the layer 44 (the layer 44a and the layer 44b) becomes a layer including tantalum, nitrogen, and oxygen or a layer including tantalum and oxygen.

Thus, the formation of the layer 44 (the layer 44a and the layer 44b) is preferably controlled. Specifically, the formation of the layer 44 is controlled in the following manners: the thickness of the layer 44 is made small; the difference between the electron affinity of the layer 44 and the electron affinity of the conductive layer 40 (the conductive layer 40a and the conductive layer 40b) (energy barrier) is made small; the interface state formed at and near the interface between the layer 44 and the semiconductor layer 30 is reduced; and the like. More specifically, the thickness of the layer 44 is set to greater than or equal to 0.1 nm and less than or equal to 3 nm, preferably greater than or equal to 0.5 nm and less than or equal to 2 nm. By controlling the formation of the layer 44, a current between the conductive layer 40 and the semiconductor layer 30 can easily flow, leading to improvement in the reliability of the transistor. Furthermore, the transistor becomes thermally stable and can be stably operated even at high temperature.

Note that the thickness of the layer 44 can be measured by observing a cross-sectional shape of the layer 44 and its vicinity with a transmission electron microscope (TEM) or the like in some cases.

Furthermore, the thickness of the layer 44 can sometimes be calculated by composition line analysis of the layer 44 and its vicinity with energy dispersive X-ray spectroscopy (EDX). For example, the thickness of the layer 44 is the difference between the position (depth) of the interface between the layer 44 and the semiconductor layer 30 and the position (depth) of the interface between the conductive layer 40 and the layer 44. In the profile of quantitative values of elements in the depth direction, which is obtained from EDX line analysis, the position (depth) of the interface between the layer 44 and the semiconductor layer 30 is regarded as a depth at which the quantitative value of a metal that is the main component of the semiconductor layer 30 but is not the main component of the conductive layer 40 becomes half. Moreover, the position (depth) of the interface between the conductive layer 40 and the layer 44 is regarded as a depth at which the quantitative value of oxygen of the semiconductor layer 30 becomes half. In this manner, the thickness of the layer 44 can be calculated.

For the control of the formation of the layer 44, a conductive material that has oxidation resistance (that is less likely to be oxidized) is preferably used as the conductive layer 40. Preferably, a metal nitride such as titanium nitride, tantalum nitride, molybdenum nitride, or tungsten nitride, for example, is preferably used as the conductive layer 40. Preferably, the crystallinity of the conductive layer 40 is increased and the density of the conductive layer 40 is increased. Also preferably, the temperature during the heat treatment performed after the formation of the conductive layer 40 is low. Accordingly, the conductive layer 40 is less likely to be oxidized, so that the formation of the layer 44 can be controlled and the thickness of the layer 44 can be reduced.

For the control of the formation of the layer 44, a layer between the conductive layer 40a and the semiconductor layer 30 and a layer between the conductive layer 40b and the semiconductor layer 30 may be provided. Such layers prevent a direct contact between the conductive layer 40a and the semiconductor layer 30 and a direct contact between the conductive layer 40b and the semiconductor layer 30, so that the oxidation of the conductive layer 40a and the conductive layer 40b can be inhibited. Thus, the layers preferably have a function of inhibiting oxidation of the conductive layer 40a and the conductive layer 40b. The layers preferably have a function of inhibiting the passage of oxygen.

A metal oxide including the element M may be used for the above layers. In particular, aluminum, gallium, yttrium, or tin is preferably used as the element M. The concentration of the element M is preferably higher in the above layers than in the semiconductor layer 30. Gallium oxide may be used for the above layers. A metal oxide such as an In-M-Zn oxide may be used for the above layers. Specifically, the atomic ratio of the element M to In in the metal oxide used for the above layers is preferably greater than the atomic ratio of the element M to In in the semiconductor layer 30. The thickness of each of the above layers is preferably greater than or equal to 0.5 nm and less than or equal to 5 nm, more preferably greater than or equal to 1 nm and less than or equal to 3 nm. The above layers preferably have crystallinity. When the above layers have crystallinity, release of oxygen in the above layers can be inhibited efficiently. For example, when the above layers have a crystal structure such as a hexagonal crystal structure, release of oxygen in the semiconductor layer 30 can sometimes be inhibited.

According to the description so far, a reduction in the carrier concentration in the oxide semiconductor used for the channel formation region of a transistor increases the threshold voltage of the transistor and decreases the subthreshold swing value, which can reduce the off-state current of the transistor to increase the reliability. Note that when the threshold voltage of the transistor is increased and the subthreshold swing value is decreased, the off-state current of the transistor can be further reduced by a reduction in the leakage current of the transistor, thereby further increasing the reliability.

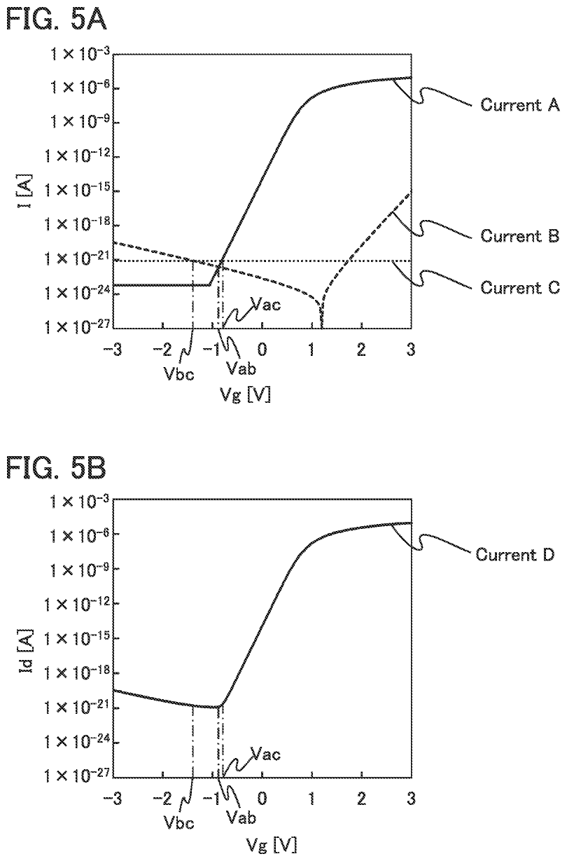

The leakage current of a transistor is described here with reference to FIG. 5A and FIG. 5B. Note that the transistor includes a first gate, a second gate, a first gate insulating layer, a second gate insulating layer, a semiconductor layer including a channel formation region, a source, and a drain.

FIG. 5A is a schematic diagram of the current (I)-gate voltage (Vg) characteristics of the transistor, and FIG. 5B is a schematic diagram of the drain current (Id)-gate voltage (Vg) characteristics of the transistor. In FIG. 5A and FIG. 5B, the horizontal axis represents a change in the voltage (Vg) [V] applied to the first gate, and the vertical axis represents a change in current (I) [A] or drain current (Id) [A]. Note that FIG. 5A and FIG. 5B are semi-log graphs with logarithmic vertical axes.

A current A indicated by the solid line in FIG. 5A is a current that flows from the drain to the source through the channel formation region. A current B indicated by the broken line in FIG. 5A is a current that flows from the drain to the first gate. A current C indicated by the dotted line in FIG. 5A is a current that flows from the drain to the second gate. Here, the current A in the non-conduction state is referred to as a subthreshold leakage current in some cases. In addition, the current B in the non-conduction state is referred to as a first leakage current in some cases. The current C in the non-conduction state is referred to as a second leakage current in some cases.

A voltage Vab shown in FIG. 5A is the value of the gate voltage at which the values of the current A and the current B are equal. A voltage Vbc shown in FIG. 5A is the value of the gate voltage at which the values of the current B and the current C are equal. A voltage Vac shown in FIG. 5A is the value of the gate voltage at which the values of the current A and the current C are equal.

A current D shown in FIG. 5B is the drain current of the transistor. The current D is observed as the sum of the current A, current B, and current C shown in FIG. 5A.

As for the drain current of the transistor having the Id-Vg characteristics shown in FIG. 5B, the ratio of the current B to the drain current is high when the gate voltage Vg is lower than the voltage Vbc; the ratio of the current C to the drain current is high when the gate voltage Vg is higher than or equal to the voltage Vbc and lower than the voltage Vac; and the ratio of the current A to the drain current is high when the gate voltage Vg is higher than or equal to the voltage Vac.

In the case where the above transistor is in the non-conduction state when no potential is applied to the first gate (Vg=0 V), the drain current when no potential is applied to the first gate (off-state current) is mainly the subthreshold leakage current. Hence, when the threshold voltage of the transistor is increased or the subthreshold swing value is decreased, the subthreshold leakage current can be made low to reduce the off-state current.

In addition, when the threshold voltage of the transistor is increased or the subthreshold swing value is decreased, the voltage Vac increases in some cases. In particular, when the voltage Vac exceeds 0 V, the second leakage current becomes the main off-state current. Therefore, in order to reduce the off-state current, the second leakage current needs to be reduced.

For a reduction in second leakage current, the thickness of the second gate insulating layer is preferably made large. For a reduction in second leakage current, the interface state formed at and near the interface between the second gate insulating layer and the semiconductor layer is preferably reduced.

In the case where the current (current C) flowing from the drain to the second gate is reduced, the voltage Vbc is higher than the voltage Vac in some cases. In particular, when the voltage Vbc exceeds 0 V, the first leakage current becomes the main off-state current. Therefore, in order to reduce the off-state current, the first leakage current needs to be reduced.

For a reduction in first leakage current, the thickness of the first gate insulating layer is preferably made large. For a reduction in first leakage current, the interface state formed at and near the interface between the first gate insulating layer and the semiconductor layer is preferably reduced.

As described above, a reduction in the leakage current (the subthreshold leakage current, the first leakage current, and the second leakage current) of a transistor can further lower the off-state current of the transistor, thereby further increasing the reliability.

As described above, the off-state current of the transistor 10 can be lower than or equal to 1 aA at temperatures that range from 180° C. to 220° C., for example. The off-state current per micrometer in channel width of the transistor 10 can be lower than or equal to 10 aA/μm at temperatures that range from 180° C. to 220° C., for example.

### <<Metal Oxide>>

As the semiconductor layer 30, a metal oxide functioning as a semiconductor is preferably used. A metal oxide that can be used as the semiconductor layer 30 of the present invention is described below.

The metal oxide preferably contains at least indium or zinc. In particular, indium and zinc are preferably contained. Furthermore, aluminum, gallium, yttrium, tin, or the like is preferably contained in addition to them. Furthermore, one kind or a plurality of kinds selected from boron, titanium, iron, nickel, germanium, zirconium, molybdenum, lanthanum, cerium, neodymium, hafnium, tantalum, tungsten, magnesium, and the like may be contained.

Here, the case where the metal oxide is an In-M-Zn oxide including indium, an element M, and zinc is considered. The element M is aluminum, gallium, yttrium, tin, or the like. Other elements that can be used as the element M include boron, titanium, iron, nickel, germanium, zirconium, molybdenum, lanthanum, cerium, neodymium, hafnium, tantalum, tungsten, magnesium, and the like. Note that it is sometimes acceptable to use a plurality of the above-described elements in combination as the element M.

Note that in this specification and the like, a metal oxide containing nitrogen is also collectively referred to as a metal oxide in some cases. A metal oxide containing nitrogen may be referred to as a metal oxynitride.

### [Structure of Metal Oxide]

Oxide semiconductors (metal oxides) are classified into a single crystal oxide semiconductor and a non-single-crystal oxide semiconductor. Examples of a non-single-crystal oxide semiconductor include a CAAC-OS (c-axis aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that it is difficult to observe a clear grain boundary even in the vicinity of distortion in the CAAC-OS. That is, formation of a grain boundary is inhibited by the distortion of a lattice arrangement. This is because the CAAC-OS can tolerate distortion owing to a low density of arrangement of oxygen atoms in the a-b plane direction, an interatomic bond length changed by substitution of a metal element, and the like.

Furthermore, the CAAC-OS tends to have a layered crystal structure (also referred to as a layered structure) in which a layer containing indium and oxygen (hereinafter, an In layer) and a layer containing the element M, zinc, and oxygen (hereinafter, an (M,Zn) layer) are stacked. Note that indium and the element M can be replaced with each other. Thus, indium exists in a metal site of the (M,Zn) layer in some cases. The element M exists in a metal site of the In layer in some cases.

The CAAC-OS is a metal oxide with high crystallinity. On the other hand, in the CAAC-OS, a reduction in electron mobility due to a grain boundary is less likely to occur because it is difficult to observe a clear grain boundary. Furthermore, entry of impurities, formation of defects, or the like might decrease the crystallinity of a metal oxide, which means that the CAAC-OS is a metal oxide having small amounts of impurities and defects (e.g., oxygen vacancies). Thus, a metal oxide including the CAAC-OS is physically stable. Therefore, the metal oxide including the CAAC-OS is resistant to heat and has high reliability.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

Note that an In—Ga—Zn oxide (hereinafter referred to as IGZO) that is a kind of metal oxide including indium, gallium, and zinc has a stable structure in some cases by being formed of the above-described nanocrystals. In particular, crystals of IGZO tend not to grow in the air and thus, a stable structure is obtained when IGZO is formed of smaller crystals (e.g., the above-described nanocrystals) rather than larger crystals (here, crystals with a size of several millimeters or several centimeters).

An a-like OS is a metal oxide having a structure between those of the nc-OS and an amorphous oxide semiconductor. The a-like OS contains a void or a low-density region. That is, the a-like OS has low crystallinity compared with the nc-OS and the CAAC-OS.

An oxide semiconductor (a metal oxide) can have various structures with different properties. The oxide semiconductor of one embodiment of the present invention may include two or more of an amorphous oxide semiconductor, a polycrystalline oxide semiconductor, an a-like OS, an nc-OS, and a CAAC-OS.

### [Transistor Including Metal Oxide]

Next, the case where the above metal oxide is used in a channel formation region of a transistor is described.

A metal oxide with a low carrier density is preferably used for the transistor. In the case where the carrier density of the metal oxide is reduced, the impurity concentration in the metal oxide is reduced to reduce the density of defect states. In this specification and the like, a state with a low impurity concentration and a low density of defect states is referred to as a highly purified intrinsic or substantially highly purified intrinsic state. The highly purified intrinsic or substantially highly purified intrinsic metal oxide has a low density of defect states and accordingly has a low density of trap states in some cases.

Charges trapped by the trap states in the metal oxide take a long time to be released and may behave like fixed charges. Thus, a transistor whose channel formation region includes a metal oxide having a high density of trap states has unstable electrical characteristics in some cases.

Accordingly, in order to obtain stable electrical characteristics of the transistor, it is effective to reduce the impurity concentration in the metal oxide. In addition, in order to reduce the impurity concentration in the metal oxide, the impurity concentration in an adjacent film is also preferably reduced. Examples of impurities include hydrogen, nitrogen, an alkali metal, an alkaline earth metal, iron, nickel, and silicon.

### [Impurities]

Here, the influence of each impurity in the metal oxide is described.

When the metal oxide contains an alkali metal or an alkaline earth metal, defect states are formed and carriers are generated in some cases. Thus, a transistor using a metal oxide that contains an alkali metal or an alkaline earth metal for its channel formation region is likely to have normally-on characteristics. Therefore, it is preferable to reduce the concentration of an alkali metal or an alkaline earth metal in the metal oxide. Specifically, the concentration of an alkali metal or an alkaline earth metal in the metal oxide obtained by SIMS is set lower than or equal to 1×10¹⁸ atoms/cm³, preferably lower than or equal to 2×10¹⁶ atoms/cm³.

According to one embodiment of the present invention, a semiconductor device that stably operates even at high temperature can be provided. According to one embodiment of the present invention, a semiconductor device with low off-state current can be provided. According to one embodiment of the present invention, a highly reliable semiconductor device can be provided. According to one embodiment of the present invention, a semiconductor device with a small variation can be provided. According to one embodiment of the present invention, a semiconductor device with reduced power consumption can be provided.

The structure, method, and the like described above in this embodiment can be used in appropriate combination with structures, methods, and the like described in the other embodiments and the examples.

### Embodiment 2

In this embodiment, structure examples of the transistor described in the above embodiment are described.

### Transistor Structure Example 1

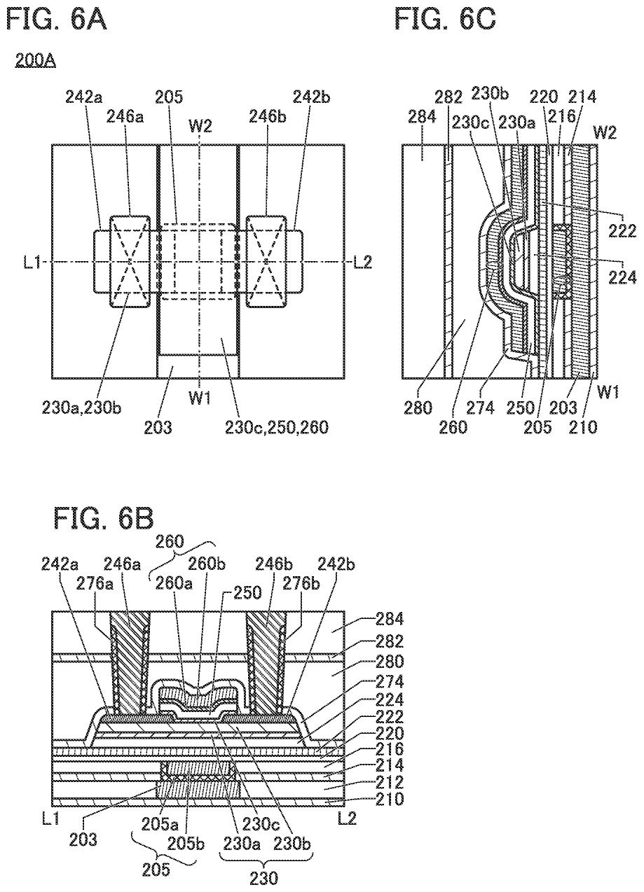

A structure example of a transistor 200A is described with reference to FIG. 6A to FIG. 6C. FIG. 6A is a top view of the transistor 200A and the neighboring area. FIG. 6B is a cross-sectional view of a portion indicated by a dashed-dotted line L1-L2 in FIG. 6A. FIG. 6C is a cross-sectional view of a portion indicated by a dashed-dotted line W1-W2 in FIG. 6A. Note that for clarification of the drawing, some components are not illustrated in the top view of FIG. 6A.

FIG. 6A to FIG. 6C illustrate the transistor 200A and an insulating layer 210, an insulating layer 212, an insulating layer 214, an insulating layer 216, an insulating layer 280, an insulating layer 282, and an insulating layer 284 that function as interlayer films. In addition, a conductive layer 246 (a conductive layer 246a and a conductive layer 246b) that is electrically connected to the transistor 200A and functions as a contact plug, and a conductive layer 203 functioning as a wiring are illustrated.

The transistor 200A includes the conductive layer 260 (a conductive layer 260a and a conductive layer 260b) functioning as a first gate (also referred to as top gate) electrode; the conductive layer 205 (a conductive layer 205a and a conductive layer 205b) functioning as a second gate (also referred to as bottom gate) electrode; an insulating layer 250 functioning as a first gate insulating layer; an insulating layer 220, an insulating layer 222, and an insulating layer 224 functioning as a second gate insulating layer; the oxide 230 (an oxide 230a, an oxide 230b, and an oxide 230c) including a region where a channel is formed; a conductive layer 242a functioning as one of a source and a drain; a conductive layer 242b functioning as the other of the source and the drain; and an insulating layer 274.

The insulating layer 210 and the insulating layer 212 function as interlayer films.

As the interlayer film, a single layer or stacked layers of an insulator such as silicon oxide, silicon oxynitride, silicon nitride oxide, aluminum oxide, hafnium oxide, tantalum oxide, zirconium oxide, lead zirconate titanate (PZT), strontium titanate (SrTiO₃), or (Ba,Sr)TiO₃ (BST) can be used. Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. Silicon oxide, silicon oxynitride, or silicon nitride may be stacked over the insulator.

For example, the insulating layer 210 preferably functions as a barrier film that inhibits entry of impurities such as water and hydrogen into the transistor 200A from the substrate side of the insulating layer 210. Accordingly, for the insulating layer 210, it is preferable to use an insulating material having a function of inhibiting diffusion of impurities such as a hydrogen atom, a hydrogen molecule, a water molecule, and a copper atom (through which the above impurities are less likely to pass). Alternatively, it is preferable to use an insulating material having a function of inhibiting diffusion of oxygen (e.g., at least one of an oxygen atom, an oxygen molecule, and the like) (through which the above oxygen is less likely to pass). For example, aluminum oxide, silicon nitride, or the like may be used for the insulating layer 210. This structure can inhibit diffusion of impurities such as hydrogen and water into the transistor 200A side from the substrate side of the insulating layer 210.

For example, the permittivity of the insulating layer 212 is preferably lower than that of the insulating layer 210. When a material with a low permittivity is used for the interlayer film, the parasitic capacitance generated between wirings can be reduced.

The conductive layer 203 is formed to be embedded in the insulating layer 212. Here, the level of the top surface of the conductive layer 203 and the level of the top surface of the insulating layer 212 can be substantially the same. Note that although a structure in which the conductive layer 203 is a single layer is illustrated, the present invention is not limited thereto. For example, the conductive layer 203 may have a multilayer structure of two or more layers. Note that for the conductive layer 203, a conductive material that has high conductivity and contains tungsten, copper, or aluminum as its main component is preferably used.

In the transistor 200A, the conductive layer 260 sometimes functions as a first gate electrode. The conductive layer 205 sometimes functions as a second gate electrode. In that case, the threshold voltage of the transistor 200A can be controlled by changing a potential applied to the conductive layer 205 independently of a potential applied to the conductive layer 260. In particular, the threshold voltage of the transistor 200A can be increased and the off-state current can be reduced by applying a negative potential to the conductive layer 205. Thus, a drain current at the time when a potential applied to the conductive layer 260 is 0 V can be lower in the case where a negative potential is applied to the conductive layer 205 than in the case where a negative potential is not applied.

For example, when the conductive layer 205 and the conductive layer 260 overlap with each other, in the case where a potential is applied to the conductive layer 260 and the conductive layer 205, an electric field generated from the conductive layer 260 and an electric field generated from the conductive layer 205 are connected and can cover a channel formation region formed in the oxide 230. That is, the channel formation region can be electrically surrounded by the electric field of the conductive layer 260 functioning as the first gate electrode and the electric field of the conductive layer 205 functioning as the second gate electrode.

Like the insulating layer 210 or the insulating layer 212, the insulating layer 214 and the insulating layer 216 function as interlayer films. For example, the insulating layer 214 preferably functions as a barrier film that inhibits entry of impurities such as water and hydrogen into the transistor 200A from the substrate side of the insulating layer 214. This structure can inhibit diffusion of impurities such as hydrogen and water into the transistor 200A side from the substrate side of the insulating layer 214. Moreover, for example, the insulating layer 216 preferably has a lower permittivity than the insulating layer 214. When a material with a low permittivity is used for the interlayer film, the parasitic capacitance generated between wirings can be reduced.

The conductive layer 205 functioning as the second gate electrode has a stacked-layer structure in which the conductive layer 205a is formed in contact with an inner wall of an opening in the insulating layer 214 and the insulating layer 216 and the conductive layer 205b is formed further inside. Here, the top surfaces of the conductive layer 205a and the conductive layer 205b and the top surface of the insulating layer 216 can be substantially level with each other. Although the transistor 200A having a structure in which the conductive layer 205a and the conductive layer 205b are stacked is illustrated, the present invention is not limited thereto. For example, the conductive layer 205 may have a single-layer structure or a stacked-layer structure of three or more layers.

Here, for the conductive layer 205a, a conductive material that has a function of inhibiting diffusion of impurities such as a hydrogen atom, a hydrogen molecule, a water molecule, and a copper atom (through which the above impurities are less likely to pass) is preferably used. Alternatively, it is preferable to use a conductive material that has a function of inhibiting diffusion of oxygen (e.g., at least one of oxygen atoms, oxygen molecules, and the like) (the above oxygen is less likely to pass). Note that in this specification, a function of inhibiting diffusion of impurities or oxygen means a function of inhibiting diffusion of any one or all of the impurities and the oxygen.

For example, when the conductive layer 205a has a function of inhibiting diffusion of oxygen, a reduction in conductivity of the conductive layer 205b due to oxidation can be inhibited.

In the case where the conductive layer 205 doubles as a wiring, the conductive layer 205b is preferably formed using a conductive material that has high conductivity and contains tungsten, copper, or aluminum as its main component. In that case, the conductive layer 203 is not necessarily provided. Note that the conductive layer 205b is illustrated as a single layer but may have a stacked-layer structure, for example, a stack of any of the above conductive materials and titanium or titanium nitride.

The insulating layer 220, the insulating layer 222, and the insulating layer 224 function as a second gate insulating layer.

Here, it is preferable that oxygen be released from the insulating layer 224 in contact with the oxide 230 by heating. In this specification, oxygen that is released by heating is referred to as excess oxygen in some cases. For example, silicon oxide, silicon oxynitride, or the like is used for the insulating layer 224 as appropriate. When an insulating layer containing oxygen is provided in contact with the oxide 230, oxygen vacancies in the oxide 230 can be reduced and the reliability of the transistor 200A can be improved.

As the insulating layer 224, specifically, an oxide material that releases part of oxygen by heating is preferably used. An oxide that releases oxygen by heating is an oxide in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably higher than or equal to 100° C. and lower than or equal to 700° C., or higher than or equal to 100° C. and lower than or equal to 400° C.

The insulating layer 222 preferably has a barrier property. The insulating layer 222 having a barrier property functions as a layer that inhibits entry of impurities such as hydrogen into the transistor 200A from the surroundings of the transistor 200A.

For the insulating layer 222, a single layer or stacked layers of an insulating layer containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. As miniaturization and high integration of transistors progress, a problem such as leakage current may arise because of a thinner gate insulating layer. When a high-k material is used for an insulating layer functioning as the gate insulating layer, a gate potential during operation of the transistor can be reduced while the physical thickness is maintained.

For example, it is preferable that the insulating layer 220 be thermally stable. For example, silicon oxide and silicon oxynitride, which have thermal stability, are preferable. Furthermore, combination of an insulator which is a high-k material and silicon oxide or silicon oxynitride enables formation of an insulating layer 220 with a stacked-layer structure with thermal stability and a high dielectric constant.

Note that the second gate insulating layer is shown to have a three-layer stacked structure in FIG. 6B and FIG. 6C, but may have a single-layer structure or a stacked-layer structure of two layers or four or more layers. In that case, without limitation to a stacked-layer structure formed of the same material, a stacked-layer structure formed of different materials may be employed.

The oxide 230 including a region functioning as the channel formation region includes the oxide 230a, the oxide 230b over the oxide 230a, and the oxide 230c over the oxide 230b. Including the oxide 230a under the oxide 230b makes it possible to inhibit diffusion of impurities into the oxide 230b from the components formed below the oxide 230a. Moreover, including the oxide 230c over the oxide 230b makes it possible to inhibit diffusion of impurities into the oxide 230b from the components formed above the oxide 230c. As the oxide 230, the metal oxide functioning as a semiconductor, which is described in the above embodiment, can be used.

The transistor 200A illustrated in FIG. 6A and FIG. 6B includes regions where the conductive layers 242 (the conductive layer 242a and the conductive layer 242b) overlap with the oxide 230c, the insulating layer 250, and the conductive layer 260. With this structure, a transistor having a high on-state current can be provided. Moreover, a transistor having high controllability can be provided.

One of the conductive layers 242 functions as a source electrode and the other functions as a drain electrode.

For the conductive layer 242, a metal such as aluminum, titanium, chromium, nickel, copper, yttrium, zirconium, molybdenum, silver, tantalum, or tungsten or an alloy containing any of the metals as its main component can be used. In particular, a metal nitride film of tantalum nitride or the like is preferable because it has a barrier property against hydrogen or oxygen and its oxidation resistance is high.

Although FIG. 6B illustrates the conductive layer 242 with a single-layer structure, a stacked-layer structure of two or more layers may be employed. For example, it is preferable to stack a tantalum nitride film and a tungsten film. Alternatively, a titanium film and an aluminum film may be stacked. Further alternatively, a two-layer structure where an aluminum film is stacked over a tungsten film, a two-layer structure where a copper film is stacked over a copper-magnesium-aluminum alloy film, a two-layer structure where a copper film is stacked over a titanium film, or a two-layer structure where a copper film is stacked over a tungsten film may be employed.

Other examples include a three-layer structure in which a titanium film or a titanium nitride film is formed, an aluminum film or a copper film is stacked over the titanium film or the titanium nitride film, and a titanium film or a titanium nitride film is stacked thereover; and a three-layer structure in which a molybdenum film or a molybdenum nitride film is formed, an aluminum film or a copper film is stacked over the molybdenum film or the molybdenum nitride film, and a molybdenum film or a molybdenum nitride film is stacked thereover. Note that a transparent conductive material containing indium oxide, tin oxide, or zinc oxide may be used.

A barrier layer may be provided over the conductive layer 242. The barrier layer is preferably formed using a material having a barrier property against oxygen or hydrogen. This structure can inhibit oxidation of the conductive layer 242 at the time of deposition of the insulating layer 274.

For example, a metal oxide can be used for the above barrier layer. In particular, an insulating film of aluminum oxide, hafnium oxide, gallium oxide, or the like, which has a barrier property against oxygen and hydrogen, is preferably used. Alternatively, silicon nitride formed by a chemical vapor deposition (CVD) method may be used.

When the above barrier layer is included, the range of choices for the materials of the conductive layer 242 can be expanded. For example, a material having a low oxidation resistance and high conductivity, such as tungsten or aluminum, can be used for the conductive layer 242. Moreover, for example, a conductor that can be easily deposited or processed can be used.

The insulating layer 250 functions as the first gate insulating layer.

As miniaturization and high integration of transistors progress, a problem such as leakage current may arise because of thinner gate insulating layers. In that case, the insulating layer 250 may have a stacked-layer structure like the second gate insulating layer. When the insulating layer functioning as the gate insulating layer has a stacked-layer structure of a high-k material and a thermally stable material, a gate potential during operation of the transistor can be reduced while the physical thickness is maintained. Furthermore, the stacked-layer structure can be thermally stable and have a high dielectric constant.

The conductive layer 260 functioning as a first gate electrode includes the conductive layer 260a and the conductive layer 260b over the conductive layer 260a. Like the conductive layer 205a, the conductive layer 260a is preferably formed using a conductive material having a function of inhibiting diffusion of impurities such as a hydrogen atom, a hydrogen molecule, a water molecule, and a copper atom. Alternatively, it is preferable to use a conductive material having a function of inhibiting diffusion of oxygen (e.g., at least one of an oxygen atom, an oxygen molecule, and the like).

When the conductive layer 260a has a function of inhibiting oxygen diffusion, the range of choices for the material of the conductive layer 260b can be expanded. That is, the conductive layer 260a inhibits oxidation of the conductive layer 260b, thereby preventing the decrease in conductivity.

As a conductive material having a function of inhibiting diffusion of oxygen, for example, tantalum, tantalum nitride, ruthenium, or ruthenium oxide is preferably used. For the conductive layer 260a, the oxide semiconductor layer that can be used as the oxide 230 can be used. In that case, when the conductive layer 260b is deposited by a sputtering method, the conductive layer 260a can have a reduced electric resistance to be a conductive layer.

The conductive layer 260 functions as a wiring and thus is preferably formed using a conductive layer having high conductivity. For example, a conductive material containing tungsten, copper, or aluminum as its main component can be used for the conductive layer 260b. The conductive layer 260b may have a stacked-layer structure, for example, a stack of any of the above conductive materials and titanium or titanium nitride.

The insulating layer 274 is preferably provided to cover the top surface and a side surface of the conductive layer 260, a side surface of the insulating layer 250, and the side surface of the oxide 230c. Note that an insulating material having a function of inhibiting diffusion of oxygen and impurities such as water and hydrogen is preferably used for the insulating layer 274. For example, aluminum oxide, hafnium oxide, or the like is preferably used. Alternatively, for example, a metal oxide such as magnesium oxide, gallium oxide, germanium oxide, yttrium oxide, zirconium oxide, lanthanum oxide, neodymium oxide, or tantalum oxide; silicon nitride oxide; silicon nitride; or the like can be used.

The insulating layer 274 can inhibit oxidation of the conductive layer 260. Moreover, the insulating layer 274 can inhibit diffusion of impurities such as water or hydrogen contained in the insulating layer 280 into the transistor 200A.

The insulating layer 280, the insulating layer 282, and the insulating layer 284 function as interlayer films.

Like the insulating layer 214, the insulating layer 282 preferably functions as a barrier insulating film that inhibits entry of impurities such as water or hydrogen into the transistor 200A from the outside.

Like the insulating layer 216, the insulating layer 280 and the insulating layer 284 preferably have a lower permittivity than the insulating layer 282. When a material with a low permittivity is used for the interlayer films, the parasitic capacitance generated between wirings can be reduced.

The transistor 200A may be electrically connected to another component through a plug or a wiring such as the conductive layer 246 embedded in the insulating layer 280, the insulating layer 282, and the insulating layer 284.

As a material for the conductive layer 246, a conductive material such as a metal material, an alloy material, a metal nitride material, or a metal oxide material can be used as a single layer or stacked layers, as in the conductive layer 205. For example, it is preferable to use a high-melting-point material that has both heat resistance and conductivity, such as tungsten or molybdenum. Alternatively, it is preferable to use a low-resistance conductive material such as aluminum or copper. The use of a low-resistance conductive material can reduce wiring resistance.

For example, when the conductive layer 246 has a stacked-layer structure of tantalum nitride or the like, which is a conductor having a barrier property against hydrogen and oxygen, and tungsten, which has high conductivity, diffusion of impurities from the outside can be inhibited while the conductivity of a wiring is maintained.

An insulating layer 276 (an insulating layer 276a and an insulating layer 276b) having a barrier property may be provided between the conductive layer 246 and the insulating layer 280. Providing the insulating layer 276 can prevent oxygen in the insulating layer 280 from reacting with the conductive layer 246 and oxidizing the conductive layer 246.

Furthermore, with the insulating layer 276 having a barrier property, the range of choices for the material of the conductive layer used as the plug or the wiring can be expanded. The use of a metal material having an oxygen absorbing property and high conductivity for the conductive layer 246, for example, can provide a semiconductor device with low power consumption. Specifically, a material having a low oxidation resistance and high conductivity, such as tungsten or aluminum, can be used. Moreover, for example, a conductive layer that can be easily deposited or processed can be used.

With the above structure, a semiconductor device including a transistor with a high on-state current can be provided. Alternatively, a semiconductor device including a transistor with a low off-state current can be provided. Alternatively, a semiconductor device that has small variations in electrical characteristics, stable electrical characteristics, and high reliability can be provided.

### <Constituent Material of Semiconductor Device>

Constituent materials that can be used for a semiconductor device are described below.

### [Substrate]

As a substrate where the transistor 200A is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate made of silicon carbide, silicon germanium, gallium arsenide, indium phosphide, zinc oxide, or gallium oxide. Another example is a semiconductor substrate in which an insulator region is included in the semiconductor substrate, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### [Insulator]

Examples of an insulator include an oxide, a nitride, an oxynitride, a nitride oxide, a metal oxide, a metal oxynitride, and a metal nitride oxide, each of which has an insulating property.

As miniaturization and high integration of transistors progress, for example, a problem such as leakage current may arise because of a thinner gate insulator. When a high-k material is used for the insulator functioning as a gate insulator, the voltage during operation of the transistor can be reduced while the physical thickness of the gate insulator is kept. By contrast, when a material with a low dielectric constant is used for the insulator functioning as an interlayer film, parasitic capacitance generated between wirings can be reduced. Thus, a material is preferably selected depending on the function of an insulator.

Examples of the insulator with a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor using an oxide semiconductor is surrounded by insulators having a function of inhibiting the passage of oxygen and impurities such as hydrogen (the insulating layer 214, the insulating layer 222, the insulating layer 274, and the like), the electrical characteristics of the transistor can be stable. For the insulator having a function of inhibiting the passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting the passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, aluminum titanium nitride, titanium nitride, silicon nitride oxide, or silicon nitride can be used.

In addition, the insulator functioning as the gate insulator is preferably an insulator including a region containing oxygen released by heating. For example, when a structure is employed in which silicon oxide or silicon oxynitride including a region containing oxygen released by heating is in contact with the oxide 230, oxygen vacancies included in the oxide 230 can be filled.

### [Conductor]

For the conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements as its component; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. A semiconductor having high electric conductivity, typified by polycrystalline silicon containing an impurity element such as phosphorus, or silicide such as nickel silicide may be used.

A stack including a plurality of conductive layers formed of the above materials may be used. For example, a stacked-layer structure combining a material containing the above metal element and a conductive material containing oxygen may be employed. A stacked-layer structure combining a material containing the above metal element and a conductive material containing nitrogen may be employed. A stacked-layer structure combining a material containing the above metal element, a conductive material containing oxygen, and a conductive material containing nitrogen may be employed.

Note that when an oxide is used for the channel formation region of the transistor, a stacked-layer structure combining a material containing the above metal element and a conductive material containing oxygen is preferably used for the conductor functioning as the gate electrode. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide where the channel is formed. Alternatively, a conductive material containing the above metal element and nitrogen may be used. For example, a conductive material containing nitrogen, such as titanium nitride or tantalum nitride, may be used. Alternatively, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Furthermore, indium gallium zinc oxide containing nitrogen may be used. With the use of such a material, hydrogen contained in the metal oxide where the channel is formed can be trapped in some cases. Alternatively, hydrogen entering from an external insulator or the like can be trapped in some cases.

### <Deposition Method>

An insulating material for forming the insulating layer, a conductive material for forming the electrode, or a semiconductor material for forming the semiconductor layer can be formed by a sputtering method, a spin coating method, a CVD (Chemical Vapor Deposition) method (including a thermal CVD method, an MOCVD (Metal Organic CVD) method, a PECVD (Plasma Enhanced CVD) method, a high density plasma CVD method, an LPCVD (low pressure CVD) method, an APCVD (atmospheric pressure CVD) method, and the like), an atomic layer deposition (ALD) method, a molecular beam epitaxy (MBE) method, a pulse laser deposition (PLD) method, a dipping method, a spray coating method, a droplet discharging method (e.g., an inkjet method), a printing method (e.g., screen printing or offset printing), or the like.

By a plasma CVD method, a high-quality film can be obtained at a relatively low temperature. With the use of a film formation method that does not use plasma at the time of film formation, such as an MOCVD method, an ALD method, or a thermal CVD method, damage is not easily caused on a surface where the film is formed. For example, a wiring, an electrode, an element (e.g., a transistor or a capacitor), or the like included in a memory device might be charged up by receiving charges from plasma. In that case, accumulated charges might break the wiring, electrode, element, or the like included in the memory device. By contrast, in the case of a film formation method not using plasma, such plasma damage is not caused; thus, the yield of memory devices can be increased. Moreover, since plasma damage during film formation is not caused, a film with few defects can be obtained.

Unlike a film formation method in which particles ejected from a target or the like are deposited, a CVD method and an ALD method are film formation methods in which a film is formed by reaction at a surface of an object. Thus, a CVD method and an ALD method are film formation methods that enable favorable step coverage almost regardless of the shape of an object. In particular, an ALD method enables excellent step coverage and excellent thickness uniformity and can be favorably used to cover a surface of an opening portion with a high aspect ratio, for example. On the other hand, an ALD method has a relatively low deposition rate, and thus is preferably used in combination with another film formation method with a high deposition rate, such as a CVD method, in some cases.

When a CVD method or an ALD method is used, the composition of a film to be formed can be controlled with a flow rate ratio of source gases. For example, by a CVD method or an ALD method, a film with a certain composition can be formed by the flow rate ratio of the source gases. Moreover, with a CVD method or an ALD method, by changing the flow rate ratio of the source gases while forming the film, a film whose composition is continuously changed can be formed. In the case of forming a film while changing the flow rate ratio of the source gases, as compared with the case of forming a film with the use of a plurality of deposition chambers, the time taken for the film formation can be shortened because the time taken for transfer and pressure adjustment is omitted. Thus, memory devices can be manufactured with improved productivity in some cases.

Note that in the case of forming a film by an ALD method, a gas that does not contain chlorine is preferably used as a material gas.

### Transistor Structure Example 2

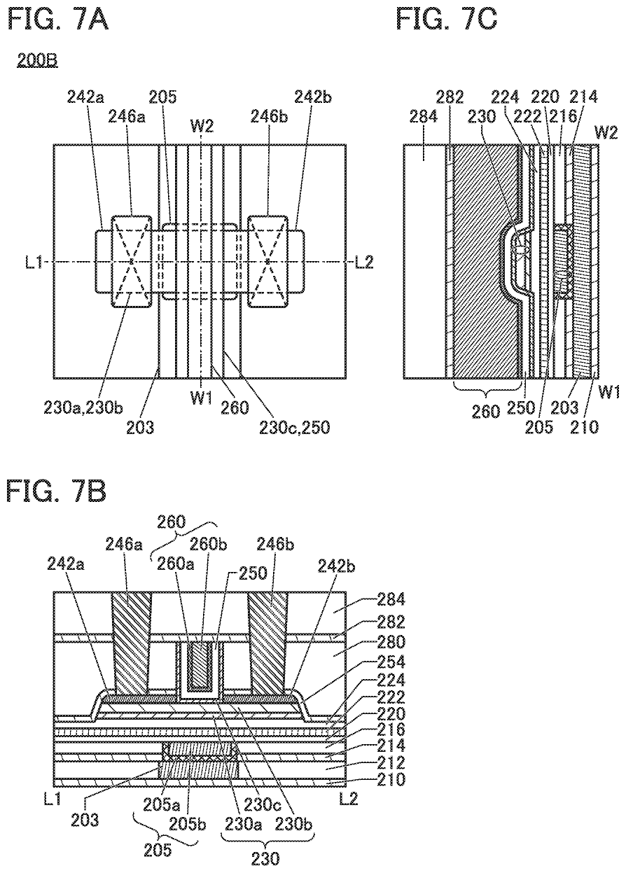

A structure example of a transistor 200B is described with reference to FIG. 7A to FIG. 7C. FIG. 7A is a top view of the transistor 200B and the neighboring area. FIG. 7B is a cross-sectional view of a portion indicated by a dashed-dotted line L1-L2 in FIG. 7A. FIG. 7C is a cross-sectional view of a portion indicated by a dashed-dotted line W1-W2 in FIG. 7A. Note that for clarification of the drawing, some components are not illustrated in the top view of FIG. 7A.

The transistor 200B is a variation example of the transistor 200A. Therefore, differences from the transistor 200A are mainly described to avoid repeated description.

In the transistor 200B illustrated in FIG. 7A to FIG. 7C, the oxide 230c, the insulating layer 250, and the conductive layer 260 are placed in an opening portion provided in the insulating layer 254 and the insulating layer 280. The oxide 230c, the insulating layer 250, and the conductive layer 260 are placed between the conductive layer 242a and the conductive layer 242b. The insulating layer 254 is placed in contact with part of the top surface of the insulating layer 224, side surfaces of the oxide 230a and the oxide 230b, part of a side surface and the top surface of the conductive layer 242a, and part of a side surface and the top surface of the conductive layer 242b.

The insulating layer 254 preferably functions as a barrier film that inhibits diffusion of impurities such as water and hydrogen into the transistor 200B from the insulating layer 280 side. For example, the insulating layer 254 preferably has lower hydrogen permeability than the insulating layer 224. Furthermore, with the structure illustrated in FIG. 7B, the insulating layer 280 is isolated from the insulating layer 224, the oxide 230a, and the oxide 230b by the insulating layer 254. Accordingly, hydrogen contained in the insulating layer 280 can be inhibited from diffusing into the oxide 230a and the oxide 230b; hence, the transistor 200B can have favorable electrical characteristics and reliability.

It is also preferable that the insulating layer 254 have a function of inhibiting diffusion of oxygen (e.g., at least one of an oxygen atom, an oxygen molecule, and the like). For example, the insulating layer 254 preferably has lower oxygen permeability than the insulating layer 280 or the insulating layer 224.

An insulating layer containing an oxide of one or both of aluminum and hafnium is preferably formed as the insulating layer 254, for example. In this case, the insulating layer 254 is preferably formed by an ALD method. An ALD method is a deposition method that provides good coverage, and thus can prevent formation of disconnection or the like due to unevenness of the insulating layer 254.

An insulating layer containing aluminum nitride may be used as the insulating layer 254, for example. Accordingly, a film having an excellent insulating property and high thermal conductivity can be obtained, and thus dissipation of heat generated in driving the transistor 200B can be increased. Alternatively, aluminum titanium nitride, titanium nitride, or the like can be used as the insulating layer 254. In that case, deposition by a sputtering method is preferable because deposition can be performed without using a highly oxidizing gas such as oxygen or ozone as a deposition gas. Alternatively, silicon nitride, silicon nitride oxide, or the like can be used.

An oxide containing gallium may be used for the insulating layer 254, for example. An oxide containing gallium is preferable because it sometimes has a function of inhibiting diffusion of one or both of hydrogen and oxygen. Note that gallium oxide, gallium zinc oxide, indium gallium zinc oxide, or the like can be used as an oxide containing gallium. Note that in the case where indium gallium zinc oxide is used as the insulating layer 254, the atomic ratio of gallium to indium is preferably high. When the atomic ratio is increased, the insulating property of the oxide can be high.

The insulating layer 254 can have a multilayer structure of two or more layers. Note that in the case of employing a multilayer structure of two or more layers, the insulating layer 254 may have a multilayer structure using different materials. For example, a stacked-layer structure of silicon oxide, silicon oxynitride, silicon nitride oxide, or silicon nitride and an insulator having a function of inhibiting the passage of oxygen and impurities such as hydrogen may be employed. As the insulator having a function of inhibiting the passage of oxygen and impurities such as hydrogen, an insulating layer containing an oxide of one or both of aluminum and hafnium can be used, for example.

### Transistor Structure Example 3

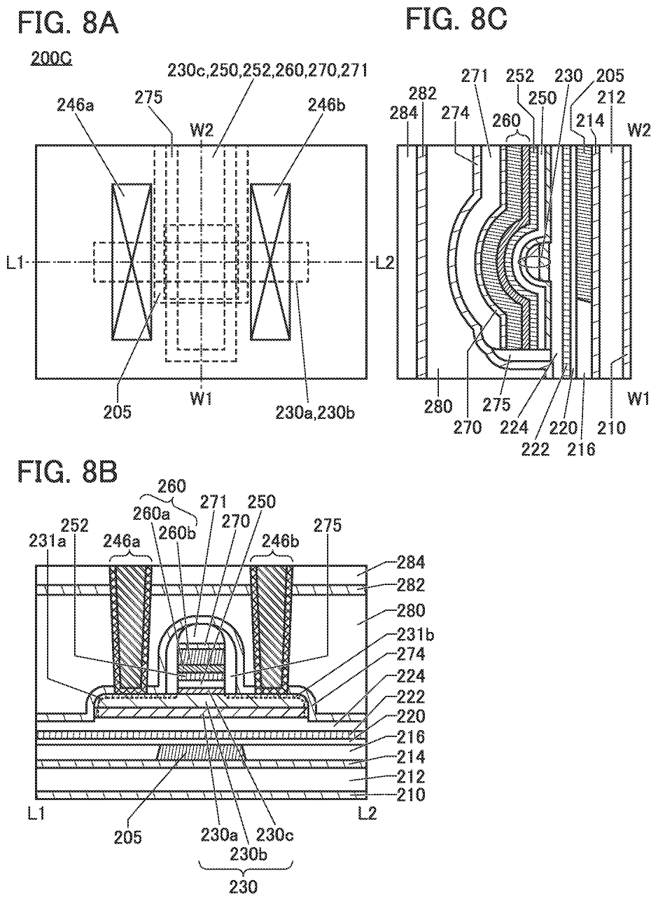

A structure example of a transistor 200C is described with reference to FIG. 8A to FIG. 8C. FIG. 8A is a top view of the transistor 200C and the neighboring area. FIG. 8B is a cross-sectional view of a portion indicated by a dashed-dotted line L1-L2 in FIG. 8A. FIG. 8C is a cross-sectional view of a portion indicated by a dashed-dotted line W1-W2 in FIG. 8A. Note that for clarification of the drawing, some components are not illustrated in the top view of FIG. 8A.

The transistor 200C is a variation example of the transistor 200A and the transistor 200B. Therefore, differences from the transistor 200A and the transistor 200B are mainly described to avoid repeated description.

Unlike in the transistor 200B illustrated in FIG. 7A to FIG. 7C, in the transistor 200C illustrated in FIG. 8A to FIG. 8C, the conductive layer 205 may be provided to have a single-layer structure. In this case, an insulating film to be the insulating layer 216 is formed over the patterned conductive layer 205, and an upper portion of the insulating film is removed by a chemical mechanical polishing (CMP) method or the like until the top surface of the conductive layer 205 is exposed. Here, the top surface of the conductive layer 205 preferably has favorable planarity. For example, the average surface roughness (Ra) of the top surface of the conductive layer 205 is less than or equal to 1 nm, preferably less than or equal to 0.5 nm, further preferably less than or equal to 0.3 nm. This allows the improvement in planarity of the insulating layer formed over the conductive layer 205 and the increase in crystallinity of the oxide 230b and the oxide 230c.

In FIG. 8A to FIG. 8C, the conductive layer 203 is not provided and the conductive layer 205 that functions as a second gate is made to function also as a wiring. Furthermore, the insulating layer 250 is provided over the oxide 230c and a metal oxide 252 is provided over the insulating layer 250. The conductive layer 260 (the conductive layer 260a and the conductive layer 260b) is provided over the metal oxide 252, and an insulating layer 270 is provided over the conductive layer 260. An insulating layer 271 is provided over the insulating layer 270.

The metal oxide 252 preferably has a function of inhibiting diffusion of oxygen. When the metal oxide 252 that inhibits oxygen diffusion is provided between the insulating layer 250 and the conductive layer 260, diffusion of oxygen into the conductive layer 260 is inhibited. That is, a reduction in the amount of oxygen supplied to the oxide 230 can be inhibited. Moreover, oxidization of the conductive layer 260 due to oxygen can be suppressed.

Note that the metal oxide 252 may function as part of a first gate electrode. For example, an oxide semiconductor layer that can be used for the oxide 230 can be used for the metal oxide 252. In this case, when the conductive layer 260 is deposited by a sputtering method, the metal oxide 252 can have a reduced electric resistance to be a conductive layer.

Note that the metal oxide 252 functions as part of a first gate insulating layer in some cases. Thus, when silicon oxide, silicon oxynitride, or the like is used for the insulating layer 250, a metal oxide that is a high-k material with a high dielectric constant is preferably used for the metal oxide 252. Such a stacked-layer structure can be thermally stable and can have a high dielectric constant. Thus, a gate potential that is applied during operation of the transistor can be reduced while the physical thickness is maintained. In addition, the equivalent oxide thickness (EOT) of the insulating layer functioning as the gate insulating layer can be reduced.

Although the metal oxide 252 in the transistor 200C is shown as a single layer, a stacked-layer structure of two or more layers may be employed. For example, a metal oxide functioning as part of the first gate electrode and a metal oxide functioning as part of the first gate insulating layer may be stacked.

With the metal oxide 252 functioning as the first gate electrode, the on-state current of the transistor 200C can be increased without a reduction in the influence of the electric field from the conductive layer 260. With the metal oxide 252 functioning as the first gate insulating layer, the distance between the conductive layer 260 and the oxide 230 is kept by the physical thicknesses of the insulating layer 250 and the metal oxide 252, so that leakage current between the conductive layer 260 and the oxide 230 can be reduced. Thus, with the stacked-layer structure of the insulating layer 250 and the metal oxide 252, the physical distance between the conductive layer 260 and the oxide 230 and the intensity of electric field applied from the conductive layer 260 to the oxide 230 can be easily adjusted as appropriate.

Specifically, the oxide semiconductor layer that can be used for the oxide 230 can also be used for the metal oxide 252 when the resistance thereof is reduced. Alternatively, a metal oxide containing one kind or two or more kinds selected from hafnium, aluminum, gallium, yttrium, zirconium, tungsten, titanium, tantalum, nickel, germanium, magnesium, and the like can be used.

In particular, aluminum oxide, hafnium oxide, an oxide containing aluminum and hafnium (hafnium aluminate), or the like, which is an insulating layer containing an oxide of one or both of aluminum and hafnium, is preferably used. In particular, hafnium aluminate has higher heat resistance than hafnium oxide. Therefore, hafnium aluminate is preferable since it is less likely to be crystallized by heat treatment in a later step. Note that the metal oxide 252 is not an essential structure. Design is appropriately set in consideration of required transistor characteristics.

For the insulating layer 270, an insulating material having a function of inhibiting the passage of oxygen and impurities such as water or hydrogen is preferably used. For example, aluminum oxide or hafnium oxide is preferably used. Thus, oxidization of the conductive layer 260 due to oxygen from above the insulating layer 270 can be inhibited. Moreover, entry of impurities such as water or hydrogen from above the insulating layer 270 into the oxide 230 through the conductive layer 260 and the insulating layer 250 can be inhibited.

The insulating layer 271 functions as a hard mask. By providing the insulating layer 271, the conductive layer 260 can be processed such that a side surface of the conductive layer 260 is substantially perpendicular; specifically, an angle formed by the side surface of the conductive layer 260 and a surface of the substrate can be greater than or equal to 75° and less than or equal to 100°, preferably greater than or equal to 80° and less than or equal to 95°.

An insulating material having a function of inhibiting the passage of oxygen and impurities such as water or hydrogen may be used for the insulating layer 271 so that the insulating layer 271 also functions as a barrier layer. In that case, the insulating layer 270 does not have to be provided.

Parts of the insulating layer 270, the conductive layer 260, the metal oxide 252, the insulating layer 250, and the oxide 230c are selected and removed using the insulating layer 271 as a hard mask, whereby their side surfaces can be substantially aligned with each other and a surface of the oxide 230b can be partly exposed.

The transistor 200C includes a region 231a and a region 231b on part of the exposed surface of the oxide 230b. One of the region 231a and the region 231b functions as a source region, and the other functions as a drain region.

The region 231a and the region 231b can be formed by addition of an impurity element such as phosphorus or boron to the exposed surface of the oxide 230b by an ion implantation method, an ion doping method, a plasma immersion ion implantation method, or plasma treatment, for example. In this embodiment and the like, an “impurity element” refers to an element other than main constituent elements.

Alternatively, the region 231a and the region 231b can be formed in such manner that, after part of the surface of the oxide 230b is exposed, a metal film is formed and then heat treatment is performed so that the element contained in the metal film is diffused into the oxide 230b.

The electrical resistivity of regions of the oxide 230b to which the impurity element is added decreases. For that reason, the region 231a and the region 231b are sometimes referred to “impurity regions” or “low-resistance regions”.

The region 231a and the region 231b can be formed in a self-aligned manner by using the insulating layer 271 or the conductive layer 260 as a mask. Accordingly, the conductive layer 260 does not overlap with the region 231a or the region 231b, so that the parasitic capacitance can be reduced. Moreover, an offset region is not formed between a channel formation region and the source region or the drain region (the region 231a or the region 231b). The formation of the region 231a and the region 231b in a self-aligned manner achieves an increase in on-state current, a reduction in threshold voltage, and an improvement in operating frequency, for example.

Note that an offset region may be provided between the channel formation region and the source region or the drain region in order to further reduce the off-state current. The offset region is a region where the electrical resistivity is high and a region where the above-described addition of the impurity element is not performed. The offset region can be formed by the above-described addition of the impurity element after the formation of an insulating layer 275. In this case, the insulating layer 275 serves as a mask like the insulating layer 271 or the like. Thus, the impurity element is not added to a region of the oxide 230b overlapped by the insulating layer 275, so that the electrical resistivity of the region can be kept high.

The transistor 200C includes the insulating layer 275 on the side surfaces of the insulating layer 270, the conductive layer 260, the metal oxide 252, the insulating layer 250, and the oxide 230c. The insulating layer 275 is preferably an insulating layer having a low dielectric constant. For example, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like is preferably used. In particular, silicon oxide, silicon oxynitride, silicon nitride oxide, or porous silicon oxide is preferably used for the insulating layer 275, in which case an excess-oxygen region can be easily formed in the insulating layer 275 in a later step. Silicon oxide and silicon oxynitride are preferable because of their thermal stability. The insulating layer 275 preferably has a function of diffusing oxygen.

The transistor 200C also includes the insulating layer 274 over the insulating layer 275 and the oxide 230. The insulating layer 274 is preferably deposited by a sputtering method. When a sputtering method is used, an insulating layer containing few impurities such as water or hydrogen can be deposited. For example, aluminum oxide is preferably used for the insulating layer 274.

Note that an oxide film obtained by a sputtering method may extract hydrogen from the structure body over which the oxide film is deposited. Thus, the hydrogen concentration in the oxide 230 and the insulating layer 275 can be reduced when the insulating layer 274 absorbs hydrogen and water from the oxide 230 and the insulating layer 275.

### Transistor Structure Example 4

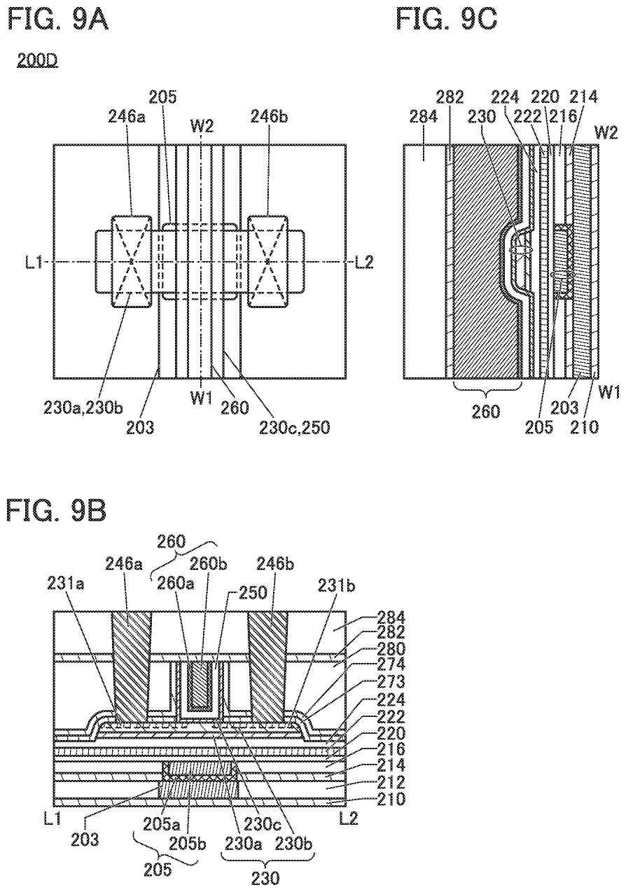

A structure example of a transistor 200D is described with reference to FIG. 9A to FIG. 9C. FIG. 9A is a top view of the transistor 200D and the neighboring area. FIG. 9B is a cross-sectional view of a portion indicated by a dashed-dotted line L1-L2 in FIG. 9A. FIG. 9C is a cross-sectional view of a portion indicated by a dashed-dotted line W1-W2 in FIG. 9A. Note that for clarification of the drawing, some components are not illustrated in the top view of FIG. 9A.

The transistor 200D is a variation example of the transistor 200B. Therefore, differences from the transistor 200B are mainly described to avoid repeated description.

In FIG. 9B, the insulating layer 274 is positioned between the insulating layer 280 and the transistor 200C. An insulating material having a function of inhibiting diffusion of oxygen and impurities such as water and hydrogen is preferably used for the insulating layer 274. For example, aluminum oxide, hafnium oxide, or the like is preferably used. Alternatively, for example, a metal oxide such as magnesium oxide, gallium oxide, germanium oxide, yttrium oxide, zirconium oxide, lanthanum oxide, neodymium oxide, or tantalum oxide; silicon nitride oxide; silicon nitride; or the like can be used.

The insulating layer 274 can inhibit diffusion of impurities such as water or hydrogen contained in the insulating layer 280 into the oxide 230b through the oxide 230c and the insulating layer 250. Furthermore, oxidation of the conductive layer 260 due to excess oxygen contained in the insulating layer 280 can be inhibited.

In FIG. 9B, the conductive layer 242 is not provided, and the transistor 200C includes a region 231a and a region 231b on part of the exposed surface of the oxide 230b. One of the region 231a and the region 231b functions as a source region, and the other functions as a drain region. Moreover, an insulating layer 273 is provided between the oxide 230b and the insulating layer 274.

The region 231 (the region 231a and the region 231b) illustrated in FIG. 9B is a region where an element that reduces the resistance of the oxide 230b is added to the oxide 230b. The region 231 can be formed using a dummy gate, for example.

Specifically, the dummy gate is provided over the oxide 230b, and an element that reduces the resistance of the oxide 230b is preferably added using the dummy gate as a mask. That is, the element is added to a region of the oxide 230 that does not overlap with the dummy gate, so that the region 231 is formed. For the addition of the element, an ion implantation method by which an ionized source gas is subjected to mass separation and then added, an ion doping method by which an ionized source gas is added without mass separation, a plasma immersion ion implantation method, or the like can be used.

As the element that reduces the resistance of the oxide 230, boron or phosphorus is typically used. Hydrogen, carbon, nitrogen, fluorine, sulfur, chlorine, titanium, a rare gas element, or the like can also be used. Typical examples of the rare gas include helium, neon, argon, krypton, and xenon. The concentration of the element is measured by SIMS or the like.

In particular, boron and phosphorus are preferably used because an apparatus used in a manufacturing line for amorphous silicon or low-temperature polysilicon can be used. Since the existing facility can be used, capital investment can be reduced.

Next, an insulating film to be the insulating layer 273 and an insulating film to be the insulating layer 274 may be deposited over the oxide 230b and the above dummy gate. The insulating film to be the insulating layer 273 and the insulating film to be the insulating layer 274 are stacked and provided, whereby a region where the region 231 and the oxide 230c and the insulating layer 250 overlap with each other can be provided.

Specifically, after an insulating film to be the insulating layer 280 is provided over the insulating film to be the insulating layer 274, the insulating film to be the insulating layer 280 is subjected to CMP treatment, whereby part of the insulating film to be the insulating layer 280 is removed and the above dummy gate is exposed. Then, when the above dummy gate is removed, part of the insulating layer 273 in contact with the above dummy gate is preferably also removed. Thus, the insulating layer 274 and the insulating layer 273 are exposed at the side surface of the opening portion provided in the insulating layer 280, and the region 231 provided in the oxide 230b is partly exposed at the bottom surface of the opening portion. Next, an oxide film to be the oxide 230c, an insulating film to be the insulating layer 250, and a conductive film to be the conductive layer 260 are formed in this order in the opening portion, and then, the oxide film to be the oxide 230c, the insulating film to be the insulating layer 250, and the conductive film to be the conductive layer 260 are partly removed by CMP treatment or the like until the insulating layer 280 is exposed; thus, the transistor 200D illustrated in FIG. 9A to FIG. 9C can be formed.

Note that the insulating layer 273 and the insulating layer 274 are not necessarily provided. Design is appropriately set in consideration of required transistor characteristics.

For the transistor 200D illustrated in FIG. 9A to FIG. 9C, existing apparatuses can be used, and the conductive layer 242 is not provided; thus, the cost can be reduced.

This embodiment can be implemented in an appropriate combination with the structures described in the other embodiments, an example, and the like.

The structure, method, and the like described above in this embodiment can be used in appropriate combination with the structures, methods, and the like described in the other embodiments and the examples.

### Embodiment 3

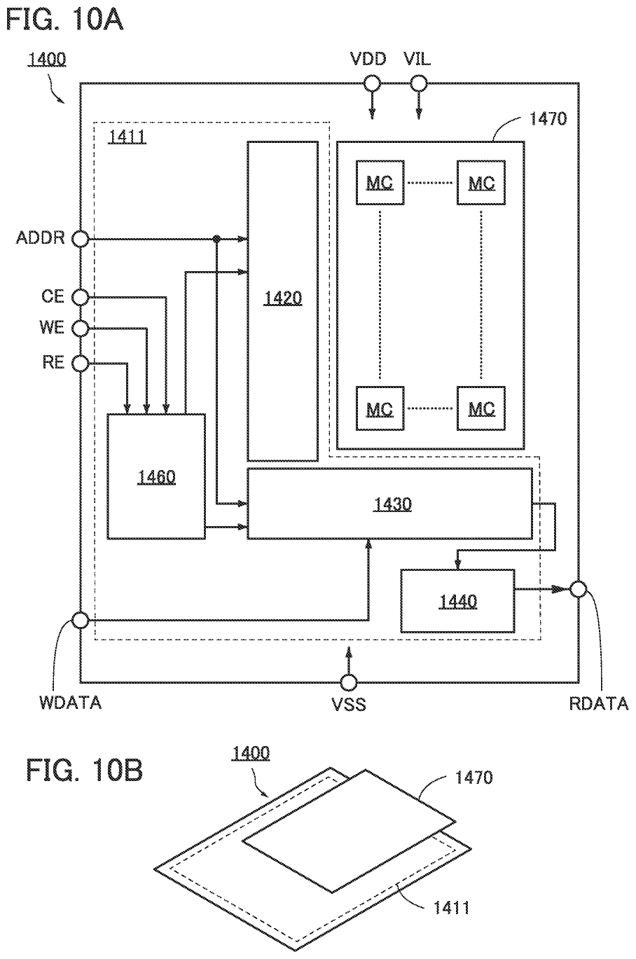

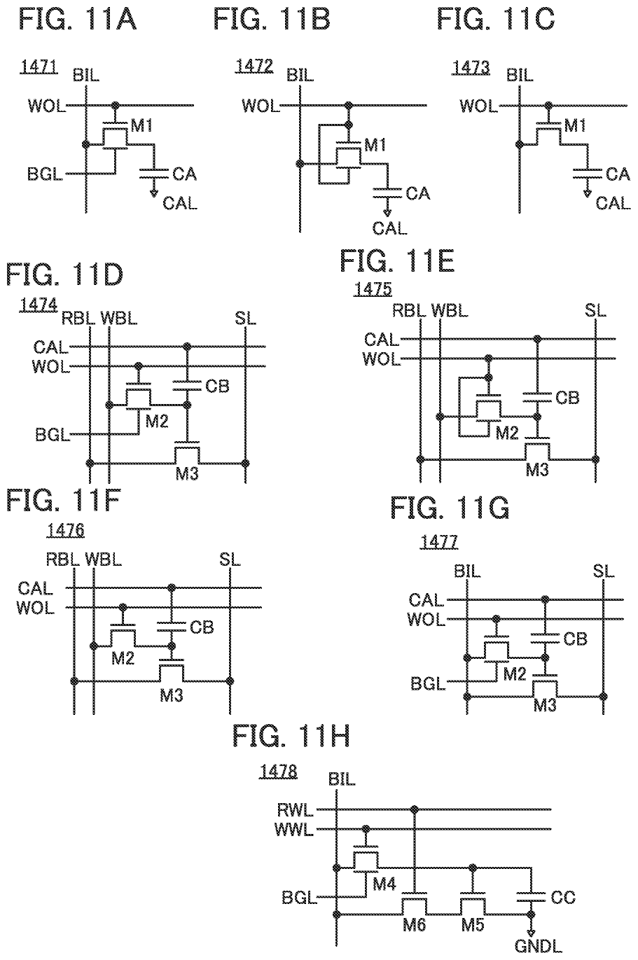

In this embodiment, a memory device of one embodiment of the present invention including a transistor including a metal oxide (hereinafter, referred to as an OS transistor in some cases) and a capacitor (hereinafter, such a memory device is referred to as an OS memory device in some cases) will be described with reference to FIG. 10A, FIG. 10B, and FIG. 11A to FIG. 11H. The OS memory device is a memory device including at least a capacitor and an OS transistor that controls charge and discharge of the capacitor. Since the off-state current of the OS transistor is extremely low, the OS memory device has excellent retention characteristics and can function as a nonvolatile memory.

### <Structure Example of Memory Device>

FIG. 10A illustrates a structure example of the OS memory device. A memory device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes a column decoder, a precharge circuit, a sense amplifier, and a write circuit, for example. The precharge circuit has a function of precharging wirings. The sense amplifier has a function of amplifying a data signal read from a memory cell. Note that the wirings are wirings connected to memory cells included in the memory cell array 1470, which will be described in detail later. An amplified data signal is output to the outside of the memory device 1400 as a data signal RDATA through the output circuit 1440. The row circuit 1420 includes a row decoder and a word line driver circuit, for example, and can select a row to be accessed.

As power supply voltages, a low power supply voltage (VSS), a high power supply voltage (VDD) for the peripheral circuit 1411, and a high power supply voltage (VIL) for the memory cell array 1470 are supplied to the memory device 1400 from the outside. In addition, control signals (CE, WE, and RE), an address signal ADDR, and a data signal WDATA are input to the memory device 1400 from the outside. The address signal ADDR is input to the row decoder and the column decoder, and the data signal WDATA is input to the write circuit.

The control logic circuit 1460 processes the control signals (CE, WE, and RE) input from the outside, and generates control signals for the row decoder and the column decoder. The control signal CE is a chip enable signal, the control signal WE is a write enable signal, and the control signal RE is a read-out enable signal. Signals processed by the control logic circuit 1460 are not limited thereto, and other control signals are input as necessary.

The memory cell array 1470 includes a plurality of memory cells MC arranged in a matrix and a plurality of wirings. Note that the number of the wirings that connect the memory cell array 1470 to the row circuit 1420 depends on the structure of the memory cell MC, the number of the memory cells MC in a column, and the like. The number of the wirings that connect the memory cell array 1470 to the column circuit 1430 depends on the structure of the memory cell MC, the number of the memory cells MC in a row, and the like.

Note that FIG. 10A illustrates an example in which the peripheral circuit 1411 and the memory cell array 1470 are formed on the same plane; however, this embodiment is not limited thereto. For example, as illustrated in FIG. 10B, the memory cell array 1470 may be provided to overlap part of the peripheral circuit 1411. For example, the sense amplifier may be provided below the memory cell array 1470 so that they overlap with each other.

FIG. 11A to FIG. 11H show structure examples of a memory cell applicable to the memory cell MC.

### [DOSRAM]

FIG. 11A to FIG. 11C illustrate circuit structure examples of a memory cell of a DRAM. In this specification and the like, a DRAM using a memory cell including one OS transistor and one capacitor is referred to as DOSRAM (registered trademark) (Dynamic Oxide Semiconductor Random Access Memory) in some cases. A memory cell 1471 illustrated in FIG. 11A includes a transistor M1 and a capacitor CA. Note that the transistor M1 includes a gate (also referred to as a top gate in some cases) and a back gate.

A first terminal of the transistor M1 is connected to a first terminal of the capacitor CA. A second terminal of the transistor M1 is connected to a wiring BIL. The gate of the transistor M1 is connected to a wiring WOL. The back gate of the transistor M1 is connected to a wiring BGL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. In the time of data writing and data reading, a low-level potential is preferably applied to the wiring CAL. The wiring BGL functions as a wiring for applying a potential to the back gate of the transistor M1. Applying a given potential to the wiring BGL can increase or decrease the threshold voltage of the transistor M1.

The memory cell MC is not limited to the memory cell 1471, and its circuit structure can be changed. For example, in the memory cell MC, the back gate of the transistor M1 may be connected to the wiring WOL instead of the wiring BGL as in a memory cell 1472 illustrated in FIG. 11B. As another example, the memory cell MC may be configured with a single-gate transistor, that is, the transistor M1 that does not have a back gate, like a memory cell 1473 illustrated in FIG. 11C.

In the case where the semiconductor device described in the above embodiment is used in the memory cell 1471 and the like, the transistor described in the above embodiment can be used as the transistor M1. When an OS transistor is used as the transistor M1, the leakage current of the transistor M1 can be extremely low. That is, written data can be retained for a long time with the use of the transistor M1; thus, the frequency of refresh of the memory cell can be reduced. Alternatively, the refresh operation of the memory cell can be omitted. In addition, the extremely low leakage current allows multi-level data or analog data to be retained in the memory cell 1471, the memory cell 1472, and the memory cell 1473.

In the DOSRAM, when the sense amplifier is provided below the memory cell array 1470 so that they overlap with each other as described above, the bit line can be shortened. Thus, the bit line capacitance can be small, and the storage capacitance of the memory cell can be reduced.

### [NOSRAM]

FIG. 11D to FIG. 11G each illustrate a circuit structure example of a gain-cell memory cell including two transistors and one capacitor. A memory cell 1474 illustrated in FIG. 11D includes a transistor M2, a transistor M3, and a capacitor CB. Note that the transistor M2 includes a top gate (sometimes simply referred to as a gate) and a back gate. In this specification and the like, a memory device including a gain-cell memory cell using an OS transistor as the transistor M2 is referred to as a NOSRAM (registered trademark) (Nonvolatile Oxide Semiconductor RAM) in some cases.

A first terminal of the transistor M2 is connected to a first terminal of the capacitor CB. A second terminal of the transistor M2 is connected to a wiring WBL. A gate of the transistor M2 is connected to the wiring WOL. A back gate of the transistor M2 is connected to the wiring BGL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing, data retaining, and data reading, a low-level potential is preferably applied to the wiring CAL. The wiring BGL functions as a wiring for applying a potential to the back gate of the transistor M2. By application of a given potential to the wiring BGL, the threshold voltage of the transistor M2 can be increased or decreased.

The memory cell MC is not limited to the memory cell 1474, and its circuit structure can be changed as appropriate. For example, in the memory cell MC, the back gate of the transistor M2 may be connected to the wiring WOL instead of the wiring BGL as in a memory cell 1475 illustrated in FIG. 11E. As another example, the memory cell MC may be configured with a single-gate transistor, that is, the transistor M2 that does not have a back gate, like a memory cell 1476 illustrated in FIG. 11F. As another example, the memory cell MC may have a structure in which the wiring WBL and the wiring RBL are combined into one wiring BIL as in a memory cell 1477 illustrated in FIG. 11G.

In the case where the semiconductor device described in the above embodiment is used for the memory cell 1474 and the like, the transistor described in the above embodiment can be used as the transistor M2. When an OS transistor is used as the transistor M2, the leakage current of the transistor M2 can be extremely low. Accordingly, with the use of the transistor M2, written data can be retained for a long time, and thus the frequency of the refresh operation for the memory cell can be decreased. Alternatively, refresh operation of the memory cell can be unnecessary. In addition, owing to an extremely low leakage current, multi-level data or analog data can be retained in the memory cell 1474. The same applies to the memory cells 1475 to 1477.

Note that the transistor M3 may be a transistor containing silicon in a channel formation region (hereinafter, also referred to as a Si transistor in some cases). The conductivity type of the Si transistor may be of either an n-channel type or a p-channel type. The Si transistor has higher field-effect mobility than the OS transistor in some cases. Therefore, a Si transistor may be used as the transistor M3 functioning as a reading transistor. Furthermore, the transistor M2 can be provided to be stacked over the transistor M3 when a Si transistor is used as the transistor M3; therefore, the area occupied by the memory cell can be reduced, leading to high integration of the memory device.

Alternatively, the transistor M3 may be an OS transistor. When an OS transistor is used as each of the transistor M2 and the transistor M3, the circuit of the memory cell array 1470 can be formed using only n-channel transistors.

FIG. 11H illustrates an example of a gain-cell memory cell of one capacitor for three transistors. A memory cell 1478 illustrated in FIG. 11H includes a transistor M4 to a transistor M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wiring RBL and the wiring WBL instead of the wiring BIL.

The transistor M4 is an OS transistor including a back gate that is electrically connected to the wiring BGL. Note that the back gate and the gate of the transistor M4 may be electrically connected to each other. Alternatively, the transistor M4 may include no back gate.

Note that each of the transistor M5 and the transistor M6 may be an n-channel Si transistor or a p-channel Si transistor. Alternatively, the transistor M4 to the transistor M6 may be OS transistors, in which case the circuit of the memory cell array 1470 can be formed using only re-channel transistors.

In the case where the semiconductor device described in the above embodiment is used for the memory cell 1478, the transistor described in the above embodiment can be used as the transistor M4. When an OS transistor is used as the transistor M4, the leakage current of the transistor M4 can be extremely low.

Note that the structures of the peripheral circuit 1411, the memory cell array 1470, and the like described in this embodiment are not limited to the above. Positions and functions of these circuits, wirings connected to the circuits, circuit elements, and the like can be changed, deleted, or added as needed.

The structure described in this embodiment can be used in an appropriate combination with the structures described in the other embodiments, an example, and the like.

### Embodiment 4

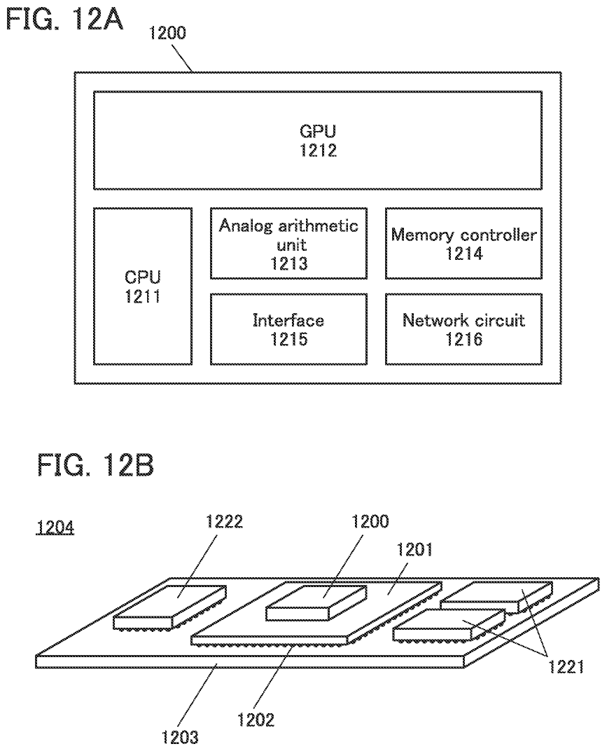

In this embodiment, an example of a chip 1200 on which the semiconductor device of the present invention is mounted will be described with reference to FIG. 12A and FIG. 12B. A plurality of circuits (systems) are mounted on the chip 1200. A technique for integrating a plurality of circuits (systems) into one chip is referred to as system on chip (SoC) in some cases.

As illustrated in FIG. 12A, the chip 1200 includes a CPU (Central Processing Unit) 1211, a GPU (Graphics Processing Unit) 1212, one or more of analog arithmetic units 1213, one or more of memory controllers 1214, one or more of interfaces 1215, one or more of network circuits 1216, and the like.

A bump (not illustrated) is provided on the chip 1200, and as illustrated in FIG. 12B, the chip 1200 is connected to a first surface of a printed circuit board (PCB) 1201. In addition, a plurality of bumps 1202 are provided on a rear side of the first surface of the PCB 1201, and the PCB 1201 is connected to a motherboard 1203.

Memory devices such as DRAMs 1221 and a flash memory 1222 may be provided over the motherboard 1203. For example, the DOSRAM described in the above embodiment can be used as the DRAM 1221. In addition, for example, the NOSRAM described in the above embodiment can be used as the flash memory 1222.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM or the DOSRAM described above can be used as the memory. Moreover, the GPU 1212 is suitable for parallel computation of a number of data and thus can be used for image processing or product-sum operation. When an image processing circuit or a product-sum operation circuit using an oxide semiconductor of the present invention is provided in the GPU 1212, image processing and product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between the memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of manufacturing processes; thus, the chip 1200 can be manufactured at low cost.

The motherboard 1203 provided with the PCB 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can execute a method in a deep neural network (DNN), a convolutional neural network (CNN), a recurrent neural network (RNN), an autoencoder, a deep Boltzmann machine (DBM), a deep belief network (DBN), or the like; thus, the chip 1200 can be used as an AI chip or the GPU module 1204 can be used as an AI system module.

The structure described in this embodiment can be used in an appropriate combination with the structures described in the other embodiments, an example, and the like.

### Embodiment 5

In this embodiment, a display device of one embodiment of the present invention will be described.

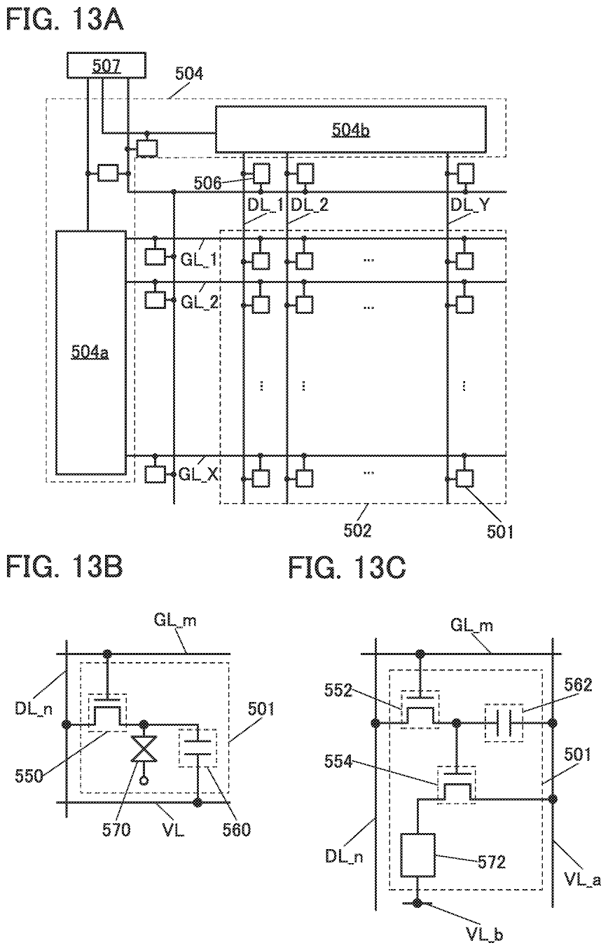

The display device in FIG. 13A includes a pixel portion 502, a driver circuit portion 504, protection circuits 506, and a terminal portion 507. Note that a structure in which the protection circuits 506 are not provided may be employed.

The transistor of one embodiment of the present invention can be used as transistors included in the pixel portion 502 and the driver circuit portion 504. The transistor of one embodiment of the present invention may also be used in the protection circuits 506.

The pixel portion 502 includes a plurality of pixel circuits 501 that drive a plurality of display elements that are arranged in X rows and Y columns (X and Y each independently represent a natural number of 2 or more).

The driver circuit portion 504 includes driver circuits such as a gate driver 504a that outputs a scanning signal to scanning lines GL_1 to GL_X and a source driver 504b that supplies a data signal to data lines DL_1 to DL_Y. The gate driver 504a includes at least a shift register. The source driver 504b is formed using a plurality of analog switches, for example. In addition, the source driver 504b may be formed using a shift register or the like.

The terminal portion 507 refers to a portion provided with terminals for inputting power, control signals, image signals, and the like to the display device from external circuits.

The protection circuit 506 is a circuit that makes, when a potential out of a certain range is applied to the wiring connected to the protection circuit, the wiring and another wiring be in conduction state. The protection circuit 506 illustrated in FIG. 13A is connected to various kinds of wirings such as scanning lines GL, which are wirings between the gate driver 504a and the pixel circuits 501, and the data lines DL, which are wirings between the source driver 504b and the pixel circuits 501.

The gate driver 504a and the source driver 504b may be provided over a substrate over which the pixel portion 502 is provided, or a substrate where a gate driver circuit or a source driver circuit is separately formed (e.g., a driver circuit board formed using a single crystal semiconductor film or a polycrystalline semiconductor film) may be mounted on the substrate by COG (Chip On Glass) or TAB (Tape Automated Bonding).

The plurality of pixel circuits 501 illustrated in FIG. 13A can have any of the configurations illustrated in FIG. 13B and FIG. 13C, for example.

The pixel circuit 501 illustrated in FIG. 13B includes a liquid crystal element 570, a transistor 550, and a capacitor 560. The data line DL_n, the scanning line GL_m, a potential supply line VL, and the like are connected to the pixel circuit 501.

The potential of one of a pair of electrodes of the liquid crystal element 570 is set in accordance with the specifications of the pixel circuit 501 as appropriate. The alignment state of the liquid crystal element 570 is set depending on written data. Note that a common potential may be supplied to one of the pair of electrodes of the liquid crystal element 570 included in each of the plurality of pixel circuits 501. Moreover, a different potential may be supplied to one of the pair of electrodes of the liquid crystal element 570 of the pixel circuit 501 in each row.

The pixel circuit 501 illustrated in FIG. 13C includes a transistor, 552 a transistor 554, a capacitor 562, and a light-emitting element 572. The data line DL_n, the scanning line GL_m, a potential supply line VL_a, a potential supply line VL_b, and the like are connected to the pixel circuit 501.

A high power supply potential VDD is supplied to one of the potential supply line VL_a and the potential supply line VL_b, and a low power supply potential VSS is supplied to the other. Current flowing in the light-emitting element 572 is controlled in accordance with the potential applied to a gate of the transistor 554, whereby the luminance of light emitted from the light-emitting element 572 is controlled.

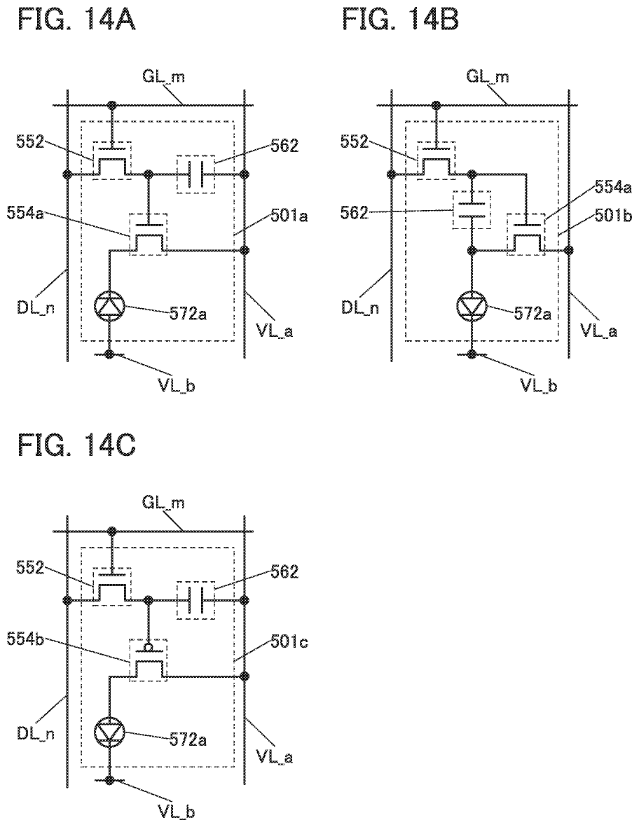

FIG. 14A shows an example in which an n-channel transistor is used as the transistor 554 in the pixel circuit 501a shown in FIG. 13C. The pixel circuit 501 shown in FIG. 14A includes the transistor 552, a transistor 554a, the capacitor 562, and a light-emitting element 572a. The transistor 552 is an n-channel transistor, and the transistor 554a is an n-channel transistor. For example, the transistor described in the above embodiment, which includes an oxide semiconductor in a channel formation region, can be used as the transistor 552, and a transistor including silicon in a channel formation region can be used as the transistor 554a.

Alternatively, for example, the transistor described in the above embodiment, which includes an oxide semiconductor in a channel formation region, can be used as each of the transistor 552 and the transistor 554a. With such a structure, the area occupied by the transistors in pixels can be reduced, so that an extremely high-definition image can be displayed.

Such a display device has extremely high resolution, and thus can be suitably used for a device for virtual reality (VR) such as a head-mounted display or a glasses-type device for augmented reality (AR). For example, even in the case of a structure in which the display portion of the display device is seen through a lens, pixels of the extremely-high-resolution display portion included in the display device are not seen when the display portion is enlarged by the lens, so that display providing a high sense of immersion can be performed. Without limitation to the above, the display device can also be suitably used for an electronic device having a relatively small display portion. For example, the display device can be suitably used in a display portion of a wearable electronic device such as a smart watch.

In the pixel circuit 501a shown in FIG. 14A, one of a source and a drain of the transistor 552 is electrically connected to the data line DL_n. The other of the source and the drain of the transistor 552 is electrically connected to one electrode of the capacitor 562 and a gate of the transistor 554a. The other electrode of the capacitor 562 is electrically connected to the potential supply line VL_a. A gate of the transistor 552 is electrically connected to the scan line GL_m. One of a source and a drain of the transistor 554a is electrically connected to the potential supply line VL_a. The other of the source and the drain of the transistor 554a is electrically connected to one of the light-emitting element 572a. The other electrode of the light-emitting element 572a is electrically connected to the potential supply line VL_b. The low power supply potential VSS is applied to the potential supply line VL_a, and the high power supply potential VDD is applied to the potential supply line VL_b.

FIG. 14B shows a structure different from that of the pixel circuit 501a shown in FIG. 14A. In the pixel circuit 501b shown in FIG. 14B, one of a source and a drain of the transistor 552 is electrically connected to the data line DL_n. The other of the source and the drain of the transistor 552 is electrically connected to one electrode of the capacitor 562 and a gate of the transistor 554a. A gate of the transistor 552 is electrically connected to the scan line GL_m. One of a source and a drain of the transistor 554a is electrically connected to the potential supply line VL_a. The other of the source and the drain of the transistor 554a is electrically connected to the other electrode of the capacitor 562 and the one electrode of the light-emitting element 572a. The other electrode of the light-emitting element 572a is electrically connected to the potential supply line VL_b. The high power supply potential VDD is applied to the potential supply line VL_a, and the low power supply potential VSS is applied to the potential supply line VL_b.

FIG. 14C shows an example in which a p-channel transistor is used as the transistor 554 in the pixel circuit 501 shown in FIG. 13C. A pixel circuit 501c shown in FIG. 14C includes the transistor 552, a transistor 554b, the capacitor 562, and a light-emitting element 572a. The transistor 552 is an n-channel transistor, and the transistor 554b is a p-channel transistor. For example, the transistor described in the above embodiment, which includes an oxide semiconductor in a channel formation region, can be used as the transistor 552, and a transistor including silicon in a channel formation region can be used as the transistor 554b.

In the pixel circuit 501c shown in FIG. 14C, one of a source and a drain of the transistor 552 is electrically connected to the data line DL_n. The other of the source and the drain of the transistor 552 is electrically connected to one electrode of the capacitor 562 and a gate of the transistor 554b. The other electrode of the capacitor 562 is electrically connected to the potential supply line VL_a. A gate of the transistor 552 is electrically connected to the scan line GL_m. One of a source and a drain of the transistor 554b is electrically connected to the potential supply line VL_a. The other of the source and the drain of the transistor 554a is electrically connected to one electrode of the light-emitting element 572a. The other electrode of the light-emitting element 572a is electrically connected to the potential supply line VL_b. The high power supply potential VDD is applied to the potential supply line VL_a, and the low power supply potential VSS is applied to the potential supply line VL_b.

At least part of the structure examples, the drawings corresponding thereto, and the like exemplified in this embodiment can be implemented in combination with the other structure examples, the other drawings, and the like as appropriate.

At least part of this embodiment can be implemented in combination with the other embodiments and the other example described in this specification as appropriate.

### Embodiment 6

A pixel circuit including a memory for correcting gray levels displayed by pixels and a display device including the pixel circuit are described below. The transistor described in the above embodiment can be applied to transistors used in the pixel circuit illustrated below.

### <Circuit Configuration>

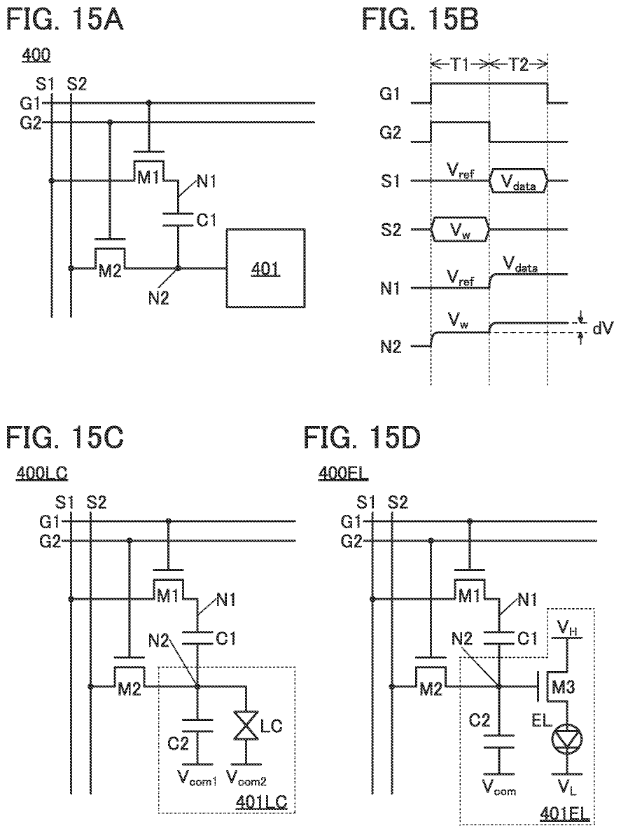

FIG. 15A is a circuit diagram of a pixel circuit 400. The pixel circuit 400 includes a transistor M1, a transistor M2, a capacitor C1, and a circuit 401. A wiring S1, a wiring S2, a wiring G1, and a wiring G2 are connected to the pixel circuit 400.

In the transistor M1, a gate is connected to the wiring G1, one of a source and a drain is connected to the wiring S1, and the other is connected to one electrode of the capacitor C1. In the transistor M2, a gate is connected to the wiring G2, one of a source and a drain is connected to the wiring S2, and the other is connected to the other electrode of the capacitor C1 and the circuit 401.

The circuit 401 is a circuit including at least one display element. Any of a variety of elements can be used as the display element, and typically, a light-emitting element such as an organic light-emitting element or an LED element, a liquid crystal element, a MEMS (Micro Electro Mechanical Systems) element, or the like can be used.

A node connecting the transistor M1 and the capacitor C1 is denoted as N1, and a node connecting the transistor M2 and the circuit 401 is denoted as N2.

In the pixel circuit 400, the potential of the node N1 can be retained when the transistor M1 is turned off. The potential of the node N2 can be retained when the transistor M2 is turned off. When a predetermined potential is written to the node N1 through the transistor M1 with the transistor M2 being in an off state, the potential of the node N2 can be changed in accordance with displacement of the potential of the node N1 owing to capacitive coupling through the capacitor C1.

Here, the transistor using an oxide semiconductor, which is described in the above embodiment, can be used as one or both of the transistor M1 and the transistor M2. Accordingly, owing to an extremely low off-state current, the potentials of the node N1 and the node N2 can be retained for a long time. Note that in the case where the period in which the potential of each node is retained is short (specifically, the case where the frame frequency is higher than or equal to 30 Hz, for example), a transistor using a semiconductor such as silicon may be used.

### <Driving Method Example>

Next, an example of a method of operating the pixel circuit 400 is described with reference to FIG. 15B. FIG. 15B is a timing chart of the operation of the pixel circuit 400. Note that for simplification of description, the influence of various kinds of resistance such as wiring resistance, parasitic capacitance of a transistor, a wiring, or the like, the threshold voltage of the transistor, and the like is not taken into account here.

In the operation shown in FIG. 15B, one frame period is divided into a period T1 and a period T2. The period T1 is a period in which a potential is written to the node N2, and the period T2 is a period in which a potential is written to the node N1.

### [Period T1]

In the period T1, a potential for turning on the transistor is supplied to both the wiring G1 and the wiring G2. In addition, a potential V_{ref} that is a fixed potential is supplied to the wiring S1, and a first data potential V_{w} is supplied to the wiring S2.

The potential V_{ref} is supplied from the wiring S1 to the node N1 through the transistor M1. The first data potential V_{w} is supplied to the node N2 from the wiring S2 through the transistor M2. Accordingly, a potential difference V_{w}−V_{ref} is retained in the capacitor C1.

### [Period T2]

Next, in the period T2, a potential for turning on the transistor M1 is supplied to the wiring G1, and a potential for turning off the transistor M2 is supplied to the wiring G2. A second data potential V_{data} is supplied to the wiring S1. The wiring S2 may be supplied with a predetermined constant potential or brought into floating.

The second data potential V_{data} is supplied to the node N1 through the transistor M1. At this time, capacitive coupling due to the capacitor C1 changes the potential of the node N2 in accordance with the second data potential V_{data} by a potential dV. That is, a potential that is the sum of the first data potential Vw and the potential dV is input to the circuit 401. Note that although dV is shown as a positive value in FIG. 15B, the potential dV may be a negative value. That is, the potential V_{data} may be lower than the potential V_{ref}.

Here, the potential dV is roughly determined by the capacitance of the capacitor C1 and the capacitance of the circuit 401. When the capacitance of the capacitor C1 is sufficiently larger than the capacitance of the circuit 401, the potential dV is a potential close to the second data potential V_{data}.

In the above manner, the pixel circuit 400 can generate a potential to be supplied to the circuit 401 including the display element, by combining two kinds of data signals; hence, a gray level can be corrected in the pixel circuit 400.

The pixel circuit 400 can also generate a potential exceeding the maximum potential that can be supplied to the wiring S1 and the wiring S2. For example, in the case where a light-emitting element is used, high-dynamic range (HDR) display or the like can be performed. In the case where a liquid crystal element is used, overdriving or the like can be achieved.

### Application Examples

### [Example Using Liquid Crystal Element]

A pixel circuit 400LC illustrated in FIG. 15C includes a circuit 401LC. The circuit 401LC includes a liquid crystal element LC and a capacitor C2.

In the liquid crystal element LC, one electrode is connected to the node N2 and one electrode of the capacitor C2, and the other electrode is connected to a wiring supplied with a potential V_{com2}. The other electrode of the capacitor C2 is connected to a wiring supplied with a potential V_{com1}.

The capacitor C2 functions as a storage capacitor. Note that the capacitor C2 can be omitted when not needed.

In the pixel circuit 400LC, a high voltage can be supplied to the liquid crystal element LC; thus, high-speed display can be performed by overdriving or a liquid crystal material with a high driving voltage can be employed, for example. Moreover, by supply of a correction signal to the wiring S1 or the wiring S2, a gray level can be corrected in accordance with the operating temperature, the deterioration state of the liquid crystal element LC, or the like.

### [Example Using Light-Emitting Element]

A pixel circuit 400EL illustrated in FIG. 15D includes a circuit 401EL. The circuit 401EL includes a light-emitting element EL, a transistor M3, and the capacitor C2.

In the transistor M3, a gate is connected to the node N2 and the one electrode of the capacitor C2, one of a source and a drain is connected to a wiring supplied with a potential V_{H}, and the other is connected to one electrode of the light-emitting element EL. The other electrode of the capacitor C2 is connected to a wiring supplied with a potential V_{com}. The other electrode of the light-emitting element EL is connected to a wiring supplied with a potential V_{L}.

The transistor M3 has a function of controlling a current to be supplied to the light-emitting element EL. The capacitor C2 functions as a storage capacitor. The capacitor C2 can be omitted when not needed.

Note that although the structure in which the anode side of the light-emitting element EL is connected to the transistor M3 is described here, the transistor M3 may be connected to the cathode side. In that case, the values of the potential V_{H} and the potential VL can be appropriately changed.

In the pixel circuit 400EL, a large amount of current can flow through the light-emitting element EL when a high potential is applied to the gate of the transistor M3, which enables HDR display, for example. Moreover, variation in the electrical characteristics of the transistor M3 and the light-emitting element EL can be corrected by supply of a correction signal to the wiring S1 or the wiring S2.

Note that the configuration is not limited to the circuits shown in FIG. 15C and FIG. 15D, and a configuration to which a transistor, a capacitor, or the like is further added may be employed.

At least part of this embodiment can be implemented in combination with any of the other embodiments described in this specification as appropriate.

### Embodiment 7

In this embodiment, structure examples of an electronic device for which the display device of one embodiment of the present invention is used will be described.

The display device of one embodiment of the present invention can be applied to a display portion of an electronic device or the like having a display function. Examples of such an electronic device include a digital camera, a digital video camera, a digital photo frame, a mobile phone, a portable game machine, a portable information terminal, and an audio reproducing device, in addition to electronic devices with a relatively large screen, such as a television device, a laptop personal computer, a monitor device, digital signage, a pachinko machine, and a game machine.

In particular, the display device of one embodiment of the present invention can have a high resolution, and thus can be favorably used for an electronic device having a relatively small display portion. The display device and the display module can be favorably used for, for example, the following electronic devices: a watch-type or bracelet-type information terminal device (wearable device); and a wearable device worn on a head, such as a device for VR such as a head mounted display and a glasses-type device for AR.

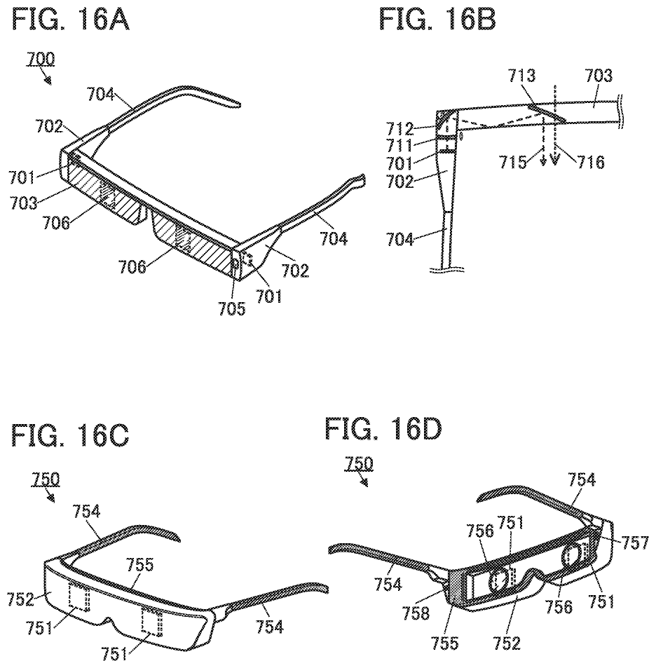

FIG. 16A is a perspective view of an electronic device 700 that is of a glasses type. The electronic device 700 includes a pair of display panels 701, a pair of housings 702, a pair of optical members 703, a pair of temples 704, and the like.

The electronic device 700 can project an image displayed on the display panel 701 onto a display region 706 of the optical member 703. Since the optical members 703 have a light-transmitting property, a user can see images displayed on the display regions 706, which are superimposed on transmission images seen through the optical members 703. Thus, the electronic device 700 is an electronic device capable of AR display.

One housing 702 is provided with a camera 705 capable of taking an image of what lies in front thereof. Although not illustrated, one of the housings 702 is provided with a wireless receiver or a connector to which a cable can be connected, whereby a video signal or the like can be supplied to the housing 702. Furthermore, when the housing 702 is provided with an acceleration sensor such as a gyroscope sensor, the orientation of the user's head can be detected and an image corresponding to the orientation can be displayed on the display region 706. Moreover, the housing 702 is preferably provided with a battery, in which case charging can be performed with or without a wire.

Next, a method for projecting an image on the display region 706 of the electronic device 700 is described with reference to FIG. 16B. The display panel 701, a lens 711, and a reflective plate 712 are provided in the housing 702. A reflective surface 713 functioning as a half mirror is provided in a portion corresponding to the display region 706 of the optical member 703.

Light 715 emitted from the display panel 701 passes through the lens 711 and is reflected by the reflective plate 712 to the optical member 703 side. In the optical member 703, the light 715 is fully reflected repeatedly by end surfaces the optical member 703 and reaches the reflective surface 713, whereby an image is projected on the reflective surface 713. Accordingly, the user can see both the light 715 reflected by the reflective surface 713 and transmitted light 716 transmitted through the optical member 703 (including the reflective surface 713).

FIG. 16B shows an example in which the reflective plate 712 and the reflective surface 713 each have a curved surface. This can increase optical design flexibility and reduce the thickness of the optical member 703, compared to the case where they have flat surfaces. Note that the reflective plate 712 and the reflective surface 713 may be flat.

The reflective plate 712 can use a component having a mirror surface, and preferably has high reflectivity. As the reflective surface 713, a half mirror utilizing reflection of a metal film may be used, but the use of prism utilizing total reflection or the like can increase the transmittance of the transmitted light 716.

Here, the housing 702 preferably includes a mechanism for adjusting the distance and angle between the lens 711 and the display panel 701. This enables focus adjustment and zooming in/out of image, for example. One or both of the lens 711 and the display panel 701 is preferably configured to be movable in the optical-axis direction, for example.

The housing 702 preferably includes a mechanism capable of adjusting the angle of the reflective plate 712. The position of the display region 706 where images are displayed can be changed by changing the angle of the reflective plate 712. Thus, the display region 706 can be placed at the most appropriate position in accordance with the position of the user's eye.

The display device of one embodiment of the present invention can be used for the display panel 701. Thus, the electronic device 700 can perform display with extremely high resolution.

FIG. 16C and FIG. 16D illustrate perspective views of an electronic device 750 that is of a goggle-type. FIG. 16C is a perspective view illustrating the front surface, the top surface, and the left side surface of the electronic device 750, and FIG. 16D is a perspective view illustrating the back surface, the bottom surface, and the right side surface of the electronic device 750.

The electronic device 750 includes a pair of display panels 751, a housing 752, a pair of temples 754, a cushion 755, a pair of lenses 756, and the like. The pair of display panels 751 is positioned to be seen through the lenses 756 inside the housing 752.

The electronic device 750 is an electronic device for VR. A user wearing the electronic device 750 can see an image displayed on the display panel 751 through the lens 756. Furthermore, when the pair of display panels 751 displays different images, three-dimensional display using parallax can be performed.

An input terminal 757 and an output terminal 758 are provided on the back side of the housing 752. To the input terminal 757, a cable for supplying a video signal from a video output device or the like, power for charging a battery provided in the housing 752, or the like can be connected. The output terminal 758 can function as, for example, an audio output terminal to which earphones, headphones, or the like can be connected. Note that in the case where audio data can be output by wireless communication or sound is output from an external video output device, the audio output terminal is not necessarily provided.

In addition, the housing 752 preferably includes a mechanism by which the left and right positions of the lens 756 and the display panel 751 can be adjusted to the optimal positions in accordance with the position of the user's eye. In addition, the housing 752 preferably includes a mechanism for adjusting focus by changing the distance between the lens 756 and the display panel 751.

The display device of one embodiment of the present invention can be used for the display panel 751. Thus, the electronic device 750 can perform display with extremely high resolution. This enables a user to feel high sense of immersion.

The cushion 755 is a portion in contact with the user's face (forehead, cheek, or the like). The cushion 755 is in close contact with the user's face, so that light leakage can be prevented, which increases the sense of immersion. A soft material is preferably used for the cushion 755 so that the cushion 755 is in close contact with the face of the user wearing the electronic device 750. For example, a material such as silicone rubber, urethane, or sponge can be used. Furthermore, when a sponge or the like whose surface is covered with cloth, leather (natural leather or synthetic leather), or the like is used, a gap is unlikely to be generated between the user's face and the cushion 755, whereby light leakage can be suitably prevented. Furthermore, using such a material is preferable because it has a soft texture and the user does not feel cold when wearing the device in a cold season, for example. The member in contact with user's skin, such as the cushion 755 or the temple 754, is preferably detachable because cleaning or replacement can be easily performed.

At least part of this embodiment can be implemented in combination with any of the other embodiments described in this specification as appropriate.

### Embodiment 8

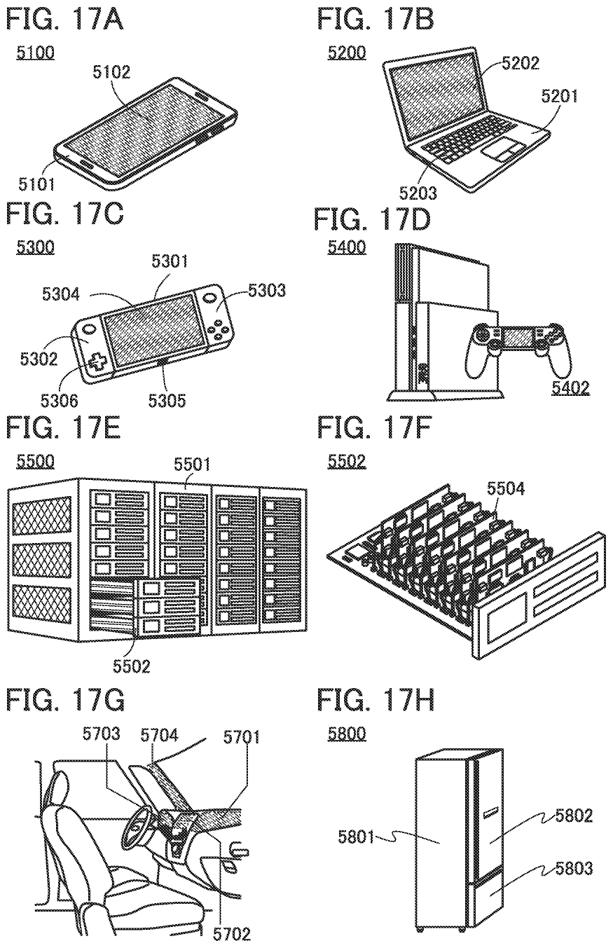

The semiconductor device of one embodiment of the present invention can be used for a chip or a processor such as a CPU or a GPU. FIG. 17A to FIG. 17H illustrate specific examples of electronic devices including a processor such as a CPU or a GPU, a chip, or a display device of one embodiment of the present invention.

Electronic devices exemplified below may include a display device of one embodiment of the present invention in a display portion. By including the display device of one embodiment of the present invention in the display portion, the electronic devices can have high resolution. In addition, the electronic devices can achieve both high resolution and a large screen.

The display portion of the electronic device can display a video with a resolution of, for example, full high definition, 4K2K, 8K4K, 16K8K, or higher. In addition, as the screen size of the display portion, the diagonal can be greater than or equal to 20 inches, greater than or equal to 30 inches, greater than or equal to 50 inches, greater than or equal to 60 inches, or greater than or equal to 70 inches.

### <Electronic Device and System>

The GPU, the chip, or the display device of one embodiment of the present invention can be incorporated into a variety of electronic devices. Examples of electronic devices include a digital camera, a digital video camera, a digital photo frame, an e-book reader, a mobile phone, a portable game machine, a portable information terminal, and an audio reproducing device in addition to electronic devices provided with a relatively large screen, such as a television device, a monitor for a desktop or notebook information terminal or the like, digital signage, and a large game machine like a pachinko machine. When the GPU or the chip of one embodiment of the present invention is provided in an electronic device, the electronic device can include artificial intelligence.

The electronic device of one embodiment of the present invention may include an antenna. When a signal is received by the antenna, the electronic device can display a video, data, or the like on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radioactive rays, flow rate, humidity, gradient, oscillation, a smell, or infrared rays).

The electronic device of one embodiment of the present invention can have a variety of functions. For example, the electronic device can have a function of displaying a variety of data (a still image, a moving image, a text image, and the like) on a display portion, a touch panel function, a function of displaying a calendar, date, time, and the like, a function of executing a variety of software (programs), a wireless communication function, and a function of reading out a program or data stored in a recording medium. FIG. 17A to FIG. 17H illustrate examples of electronic devices.

### [Information Terminal]

FIG. 17A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

The information terminal 5100 can execute an application utilizing artificial intelligence, with the use of the chip of one embodiment of the present invention. Examples of the application utilizing artificial intelligence include an application for interpreting a conversation and displaying its content on the display portion 5102; an application for recognizing letters, figures, and the like input to the touch panel of the display portion 5102 by a user and displaying them on the display portion 5102; and an application for biometric authentication using fingerprints, voice prints, or the like.

FIG. 17B illustrates a notebook information terminal 5200. The notebook information terminal 5200 includes a main body 5201 of the information terminal, a display portion 5202, and a keyboard 5203.

Like the information terminal 5100 described above, the notebook information terminal 5200 can execute an application utilizing artificial intelligence, with the use of the chip of one embodiment of the present invention. Examples of the application utilizing artificial intelligence include design-support software, text correction software, and software for automatic menu generation. Furthermore, with the use of the notebook information terminal 5200, novel artificial intelligence can be developed.

Note that although the smartphone and the notebook information terminal are respectively illustrated in FIG. 17A and FIG. 17B as examples of the electronic device, one embodiment of the present invention can be applied to an information terminal other than the smartphone and the notebook information terminal. Examples of an information terminal other than the smartphone and the notebook information terminal include a PDA (Personal Digital Assistant), a desktop information terminal, and a workstation.

### [Game Machine]

FIG. 17C illustrates a portable game machine 5300, which is an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), a video to be output to the display portion 5304 can be output to another video device (not illustrated). In that case, the housing 5302 and the housing 5303 can each function as an operating unit. Thus, a plurality of players can play a game at the same time. The chip described in the above embodiment can be incorporated into a chip provided on a substrate in the housing 5301, the housing 5302, and the housing 5303, for example.

FIG. 17D illustrates a stationary game machine 5400, which is an example of a game machine. A controller 5402 is connected to the stationary game machine 5400 with or without a wire.

Using the GPU or the chip of one embodiment of the present invention in a game machine such as the portable game machine 5300 and the stationary game machine 5400 can achieve a low-power-consumption game machine. Moreover, heat generation from a circuit can be reduced owing to low power consumption; thus, the influence of heat generation on the circuit, the peripheral circuit, and the module can be reduced.

Furthermore, when the GPU or the chip of one embodiment of the present invention is used in the portable game machine 5300, the portable game machine 5300 including artificial intelligence can be obtained.

In general, the progress of a game, the actions and words of game characters, and expressions of a phenomenon and the like in the game are determined by the program in the game; however, the use of artificial intelligence in the portable game machine 5300 enables expressions not limited by the game program. For example, questions posed by the player, the progress of the game, time, and actions and words of game characters can be changed for various expressions.

When a game requiring a plurality of players is played on the portable game machine 5300, the artificial intelligence can create a virtual game player; thus, the game can be played alone with the game player created by the artificial intelligence as an opponent.

Although the portable game machine and the stationary game machine are respectively illustrated in FIG. 17C and FIG. 17D as examples of a game machine, the game machine using the GPU or the chip of one embodiment of the present invention is not limited thereto. Examples of the game machine using the GPU or the chip of one embodiment of the present invention include an arcade game machine installed in entertainment facilities (a game center, an amusement park, and the like) and a throwing machine for batting practice installed in sports facilities.

### [Large Computer]

The GPU or the chip of one embodiment of the present invention can be used in a large computer.

FIG. 17E illustrates a supercomputer 5500 as an example of a large computer. FIG. 17F illustrates a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504, and the GPU or the chip described in the above embodiment can be mounted on the substrates.

The supercomputer 5500 is a large computer mainly used for scientific computation. In scientific computation, an enormous amount of arithmetic operation needs to be processed at a high speed; hence, power consumption is high and chips generate a large amount of heat. Using the GPU or the chip of one embodiment of the present invention in the supercomputer 5500 can achieve a low-power-consumption supercomputer. Moreover, heat generation from a circuit can be reduced owing to low power consumption; thus, the influence of heat generation on the circuit, the peripheral circuit, and the module can be reduced.

Although a supercomputer is illustrated as an example of a large computer in FIG. 17E and FIG. 17F, a large computer using the GPU or the chip of one embodiment of the present invention is not limited thereto. Examples of a large computer using the GPU or the chip of one embodiment of the present invention include a computer that provides service (a server) and a large general-purpose computer (a mainframe).

### [Moving Vehicle]

The GPU, the chip, or the display device of one embodiment of the present invention can be used in an automobile, which is a moving vehicle, and around a driver's seat in the automobile.

FIG. 17G is a view illustrating the periphery of a windshield inside an automobile as an example of a moving vehicle. FIG. 17G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, a mileage, a fuel meter, a gearshift indicator, air-condition setting, and the like. The content, layout, or the like of the display on the display panels can be changed as appropriate to suit the user's preference, so that the design can be improved. The display panel 5701 to the display panel 5703 can also be used as lighting devices.

The display panel 5704 can compensate for the view obstructed by the pillar (a blind spot) by showing an image taken by an imaging device (not illustrated) provided for the automobile. That is, displaying an image taken by the imaging device provided on the outside of the automobile leads to compensation for the blind spot and enhancement of safety. In addition, showing an image for compensating for the area which a driver cannot see makes it possible for the driver to confirm safety more easily and comfortably. The display panel 5704 can also be used as a lighting device.

Since the GPU or the chip of one embodiment of the present invention can be used as a component of artificial intelligence, the chip can be used in an automatic driving system of the automobile, for example. The chip can also be used for a system for navigation, risk prediction, or the like. The display panel 5701 to the display panel 5704 may display information regarding navigation information, risk prediction, and the like.

Although an automobile is described above as an example of a moving vehicle, moving vehicles are not limited to an automobile. Examples of moving vehicles include a train, a monorail train, a ship, and a flying object (a helicopter, an unmanned aircraft (a drone), an airplane, and a rocket), and these moving vehicles can include a system utilizing artificial intelligence when equipped with the chip of one embodiment of the present invention.

### [Electric Appliance]

FIG. 17H illustrates an electric refrigerator-freezer 5800, which is an example of an electrical appliance. The electric refrigerator-freezer 5800 includes a housing 5801, a refrigerator door 5802, a freezer door 5803, and the like.

When the chip of one embodiment of the present invention is used in the electric refrigerator-freezer 5800, the electric refrigerator-freezer 5800 including artificial intelligence can be obtained. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting the temperature to be appropriate for the foods stored in the electric refrigerator-freezer 5800, and the like.

Although the electric refrigerator-freezer is described as an example of an electrical appliance, other examples of an electrical appliance include a vacuum cleaner, a microwave oven, an electronic oven, a rice cooker, a water heater, an IH cooker, a water server, a heating-cooling combination appliance such as an air conditioner, a washing machine, a drying machine, and an audio visual appliance.

The electronic devices, the functions of the electronic devices, application examples of artificial intelligence and its effects, and the like described in this embodiment can be combined as appropriate with the description of another electronic device.

This embodiment can be implemented in an appropriate combination with the structures described in the other embodiments, the example, and the like.

### Example

In this example, the relationship between the hydrogen concentration and carrier concentration in a metal oxide, which is described in Embodiment 1, is described. Specifically, four samples including metal oxide films (Sample 1B to Sample 4B) were manufactured, and the hydrogen concentration in the metal oxide films obtained by SIMS analysis and the carrier concentration in the metal oxide films converted from sheet resistance were compared to each other.

A manufacturing method of Sample 1B and Sample 2B is described below.

A first metal oxide film was deposited to a thickness of 100 nm over a quartz substrate by a sputtering method. In the deposition of the first metal oxide film, an In—Ga—Zn oxide target with In:Ga:Zn=4:2:4.1 [atomic ratio] was used; an argon gas at 40 sccm and an oxygen gas at 5 sccm were used as a deposition gas; the deposition pressure was 0.7 Pa; the deposition power was 500 W; the substrate temperature was 130° C.; and the distance between the target and the substrate was 60 mm.

Then, first heat treatment was performed. In first heat treatment, treatment was performed at 400° C. in a nitrogen atmosphere for one hour, and treatment was successively performed at 400° C. in an oxygen atmosphere for one hour.

Then, second heat treatment was performed. As the second heat treatment, treatment for Sample 1B was performed at a temperature of 350° C. for 37 seconds in an atmosphere where a silane (SiH₄) gas was introduced at a flow rate of 1 sccm. Treatment for Sample 2B was performed at a temperature of 350° C. for 135 seconds in an atmosphere where a silane (SiH₄) gas was introduced.

Through the above steps, Sample 1B and Sample 2B were manufactured.

A manufacturing method of Sample 3B and Sample 4B is described below.

A surface of a substrate containing silicon was subjected to heat treatment in a hydrogen chloride (HCl) atmosphere, and a 100-nm-thick silicon oxide film was formed over the substrate. A metal oxide film was deposited to a thickness of 500 nm over the silicon oxide film by a sputtering method. In the deposition of the metal oxide film, an In—Ga—Zn oxide target with In:Ga:Zn=4:2:4.1 [atomic ratio] was used; an argon gas at 40 sccm and an oxygen gas at 5 sccm were used as a deposition gas; the deposition pressure was 0.7 Pa; the deposition power was 500 W; the substrate temperature was 130° C.; and the distance between the target and the substrate was 60 mm.

Then, first heat treatment was performed. In first heat treatment, treatment was performed at 400° C. in a nitrogen atmosphere for one hour, and treatment was successively performed at 400° C. in an oxygen atmosphere for one hour.

Next, a 20-nm-thick silicon nitride film was deposited over the metal oxide film by a CVD method. For the deposition of the silicon nitride film, a silane (SiH₄) gas at 20 sccm, a nitrogen gas at 600 sccm, and an ammonia (NH₃) gas at 200 sccm were used as deposition gases, the electric power was 50 W, the pressure was 200 Pa, and the substrate temperature was 270° C.

Next, the second heat treatment was performed on Sample 4B. The second heat treatment was performed at a temperature of 400° C. in a nitrogen atmosphere for one hour. Note that the second heat treatment was not performed on Sample 3B.

Through the above steps, Sample 3B and Sample 4B were manufactured.

The hydrogen concentration in the metal oxide films of Sample 1B to Sample 4B was evaluated with a SIMS analysis apparatus. Note that the analysis was performed on the surface side of the sample. Furthermore, the sheet resistance of the metal oxide films of Sample 1B to Sample 4B was measured with a sheet resistance measurer. Note that a sheet resistance measurer whose measurement upper limit was 6.0×10⁶ Ω/sq. was used.

Here, a method of converting the measured sheet resistance of the metal oxide film into the carrier concentration in the metal oxide film is described.

First, according to Formula (1), the sheet resistance Rₛ [Ω/sq.] is converted into carrier surface density N(T) [cm⁻²] at a thickness T [nm] of the metal oxide film after a reduction in thickness.

$$\begin{matrix}[ Formula 1 ] & \\ N ( T ) = \frac{1}{{R}_{s} q μ} & ( 1 )\end{matrix}$$

In Formula (1), q is a charge of a carrier (=1.602×10⁻¹⁹ C) and μ is mobility. Note that in this example, the mobility μ was assumed to be 20 cm²/(V·s).

The carrier surface density N(T) is represented by Formula (2) using the carrier concentration n(x) [cm⁻³] within a distance x [nm] from the bottom surface of the metal oxide film.

[Formula 2]

N(T)=∫₀^{T}n(x)dx (2)

The carrier concentration n(x) within a distance x [nm] from the bottom surface of the metal oxide film can be expressed using a complementary error function erfc(y) (y is a variable), as represented by Formula (3).

$$\begin{matrix}[ Formula 3 ] & \\ n ( x ) = \frac{c}{2} erfc ( \frac{a - x}{2 b} ) & ( 3 )\end{matrix}$$

Here, a, b, and c are parameters. When Formula (3) is substituted into Formula (2), the carrier surface density N(T) can be represented by Formula (4) using the parameters a, b and c.

$$\begin{matrix}[ Formula 4 ] & \\ N ( T ) = \frac{c}{2} \{ T + ( a - T ) \cdot erf ( \frac{a - T}{2 b} ) - a \cdot erf ( \frac{a}{2 b} ) + \frac{2 b}{\sqrt{π}} [ {e}^{- \frac{{( a - T )}^{2}}{4 {b}^{2}}} - {e}^{- \frac{{a}^{2}}{4 {b}^{2}}} ] \} & ( 4 )\end{matrix}$$

Here, the function erf(y) shown in Formula (4) is an error function. The error function erf(y) and the complementary error function erfc(y) have a relationship represented by Formula (5).

[Formula 5]

erf(y)+erfc(y)=1 (5)

Then, data points of the T dependence of the carrier surface density N(T) converted from the sheet resistance are fitted using Formula (4) by a least-squares method. Here, the parameters a, b, and c are fitting parameters. The values of the obtained parameters a, b, and c are substituted into Formula (3), whereby the carrier concentration n(x) for the distance x from the bottom surface of the metal oxynitride film can be calculated.

As described above, the measured sheet resistance of the metal oxide film can be converted into the carrier concentration in the metal oxide film.

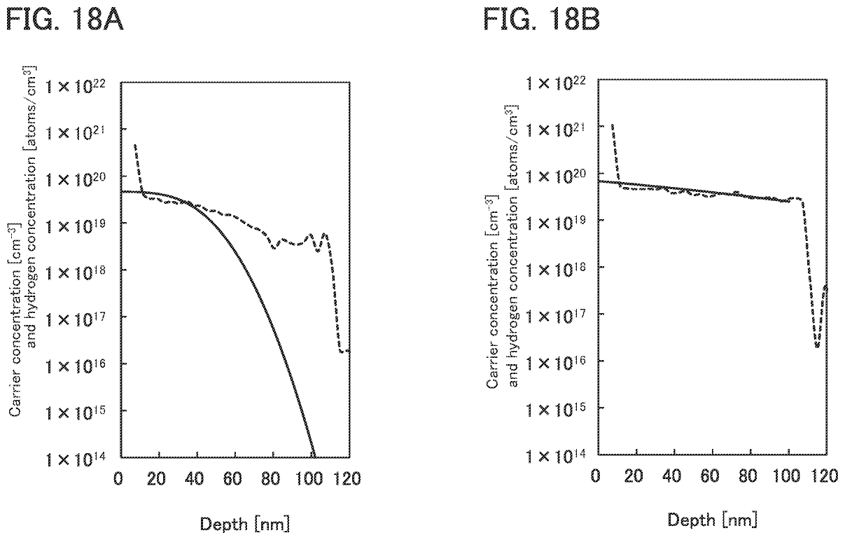

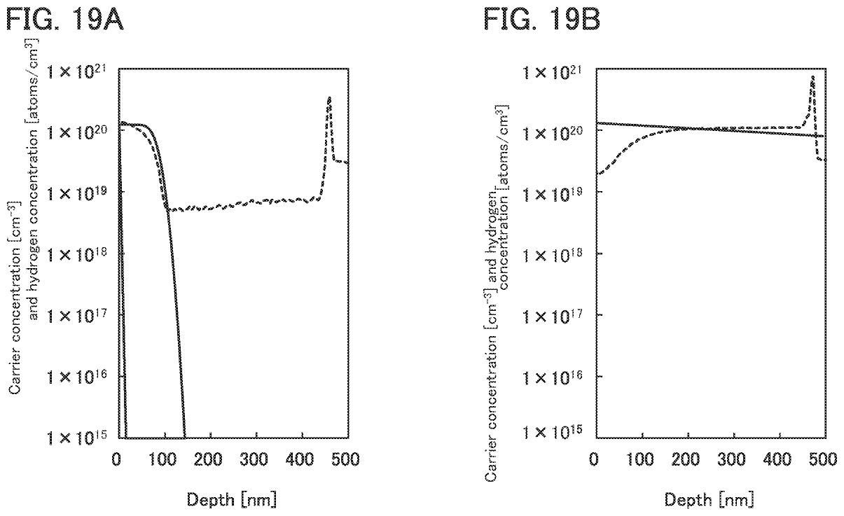

FIG. 18A to FIG. 19B show the carrier concentration in the metal oxide films which are converted from the hydrogen concentration and sheet resistance in the metal oxide films obtained by SIMS analysis. In FIG. 18A to FIG. 19B, the horizontal axis represents a depth direction (Depth) [nm] perpendicular to a film surface of the sample, and the vertical axis represents the carrier concentration [cm⁻³] in the metal oxide film or the hydrogen concentration [atoms/cm³] in the metal oxide film.

FIG. 18A shows the hydrogen concentration and carrier concentration in the metal oxide film of Sample 1B. FIG. 18B shows the hydrogen concentration and carrier concentration in the metal oxide film of Sample 2B. FIG. 19A shows the hydrogen concentration and carrier concentration in the metal oxide film of Sample 3B. FIG. 19B shows the hydrogen concentration and carrier concentration in the metal oxide film of Sample 4B.

From FIG. 18A to FIG. 19B, it is found that the profile of the hydrogen concentration in the metal oxide film substantially agrees with the profile of the carrier concentration in the metal oxide film. That is, it is found that the hydrogen concentration and the carrier concentration in the metal oxide film correlate with each other and that the hydrogen concentration in the channel formation region is preferably reduced to reduce the carrier concentration in the region.

At least part of the structure, the method, and the like described in this example can be implemented in appropriate combination with other embodiments described in this specification.

### REFERENCE NUMERALS

10: transistor, 30: semiconductor layer, 31a: region, 31b: region, 32a: region, 32b: region, 34: region, 40: conductive layer, 40a: conductive layer, 40b: conductive layer, 44: layer, 44a: layer, 44b: layer, 50: insulating layer, 60: conductive layer, 70: insulating layer, 80: conductive layer, 200A: transistor, 200B: transistor, 200C: transistor, 200D: transistor, 203: conductive layer, 205: conductive layer, 205a: conductive layer, 205b: conductive layer, 210: insulating layer, 212: insulating layer, 214: insulating layer, 216: insulating layer, 220: insulating layer, 222: insulating layer, 224: insulating layer, 230: oxide, 230a: oxide, 230b: oxide, 230c: oxide, 231: region, 231a: region, 231b: region, 242: conductive layer, 242a: conductive layer, 242b: conductive layer, 246: conductive layer, 246a: conductive layer, 246b: conductive layer, 250: insulating layer, 252: metal oxide, 254: insulating layer, 260: conductive layer, 260a: conductive layer, 260b: conductive layer, 270: insulating layer, 271: insulating layer, 273: insulating layer, 274: insulating layer, 275: insulating layer, 276: insulating layer, 276a: insulating layer, 276b: insulating layer, 280: insulating layer, 282: insulating layer, 284: insulating layer, 400: pixel circuit, 400EL: pixel circuit, 400LC: pixel circuit, 401: circuit, 401EL: circuit, 401LC: circuit, 501: pixel circuit, 501a: pixel circuit, 501b: pixel circuit, 501c: pixel circuit, 502: pixel portion, 504: driver circuit portion, 504a: gate driver, 504b: source driver, 506: protection circuit, 507: terminal portion, 550: transistor, 552: transistor, 554: transistor, 554a: transistor, 554b: transistor, 560: capacitor, 562: capacitor, 570: liquid crystal element, 572: light-emitting element, 572a: light-emitting element, 700: electronic device, 701: display panel, 702: housing, 703: optical member, 704: temple, 705: camera, 706: display region, 711: lens, 712: reflective plate, 713: reflective surface, 715: light, 716: transmitted light, 750: electronic device, 751: display panel, 752: housing, 754: temple, 755: cushion, 756: lens, 757: input terminal, 758: output terminal, 1200: chip, 1201: PCB, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 1400: memory device, 1411: peripheral circuit, 1420: row circuit, 1430: column circuit, 1440: output circuit, 1460: control logic circuit, 1470: memory cell array, 1471: memory cell, 1472: memory cell, 1473: memory cell, 1474: memory cell, 1475: memory cell, 1476: memory cell, 1477: memory cell, 1478: memory cell, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door

1. A semiconductor device comprising a metal oxide, an insulating layer, a first conductive layer, a second conductive layer, and a third conductive layer,
wherein the metal oxide comprises a first region, a second region, and a third region,
wherein the first region overlaps with the first conductive layer,
wherein the second region overlaps with the second conductive layer,
wherein the third region overlaps with the third conductive layer with the insulating layer interposed therebetween,
wherein a carrier concentration in each of the first region and the second region is higher than or equal to 5×10¹⁷ cm⁻³ and lower than 1×10¹⁹ cm⁻³, and
wherein a carrier concentration in the third region is higher than or equal to 1×10¹² cm⁻³ and lower than 5×10¹⁷ cm⁻³.

2. A semiconductor device comprising a metal oxide, an insulating layer, a first conductive layer, a second conductive layer, and a third conductive layer,
wherein the metal oxide comprises a first region, a second region, and a third region,
wherein the first region overlaps with the first conductive layer,
wherein the second region overlaps with the second conductive layer,
wherein the third region overlaps with the third conductive layer with the insulating layer interposed therebetween,
wherein a value of a ratio of a carrier concentration in the first region to a carrier concentration in the third region is greater than or equal to 1×10², and
wherein a value of a ratio of a carrier concentration in the second region to the carrier concentration in the third region is greater than or equal to 1×10².

3. The semiconductor device according to claim 1, further comprising:
a first layer between the first region and the first conductive layer; and
a second layer between the second region and the second conductive layer,
wherein the first conductive layer and the second conductive layer each comprise tantalum nitride, and
wherein the first layer and the second layer each comprise tantalum, nitrogen, and oxygen or comprise tantalum and oxygen.

4. The semiconductor device according to claim 1,
wherein a hydrogen concentration in the third region is lower than 1×10¹⁸ atoms/cm³.

5. A semiconductor device comprising a transistor,
wherein the transistor comprises a metal oxide, a first insulating layer, a second insulating layer, a first conductive layer, a second conductive layer, a third conductive layer, and a fourth conductive layer,
wherein the second insulating layer is provided over the fourth conductive layer,
wherein the metal oxide is provided over the second insulating layer,
wherein the first insulating layer is provided over the metal oxide,
wherein the third conductive layer is provided over the first insulating layer,
wherein the first conductive layer is provided over the metal oxide,
wherein the second conductive layer is provided over the metal oxide,
wherein the third conductive layer overlaps with the fourth conductive layer with the metal oxide interposed therebetween, and
wherein an off-state current of the transistor is lower than or equal to 1 aA at a temperature higher than or equal to 180° C. and lower than or equal to 220° C.

6. A semiconductor device comprising a transistor,
wherein the transistor comprises a metal oxide, a first insulating layer, a second insulating layer, a first conductive layer, a second conductive layer, a third conductive layer, and a fourth conductive layer,
wherein the second insulating layer is provided over the fourth conductive layer,
wherein the metal oxide is provided over the second insulating layer,
wherein the first insulating layer is provided over the metal oxide,
wherein the third conductive layer is provided over the first insulating layer,
wherein the first conductive layer is provided over the metal oxide,
wherein the second conductive layer is provided over the metal oxide,
wherein the third conductive layer overlaps with the fourth conductive layer with the metal oxide interposed therebetween, and
wherein an off-state current per micrometer in a channel width of the transistor is lower than or equal to 10 aA/μm at a temperature higher than or equal to 180° C. and lower than or equal to 220° C.

7. The semiconductor device according to claim 1,
wherein the metal oxide comprises indium, an element M (M is aluminum, gallium, yttrium, or tin), and zinc.

8. The semiconductor device according to claim 2, further comprising:
a first layer between the first region and the first conductive layer; and
a second layer between the second region and the second conductive layer,
wherein the first conductive layer and the second conductive layer each comprise tantalum nitride, and
wherein the first layer and the second layer each comprise tantalum, nitrogen, and oxygen or comprise tantalum and oxygen.

9. The semiconductor device according to claim 2,
wherein a hydrogen concentration in the third region is lower than 1×10¹⁸ atoms/cm³.

10. The semiconductor device according to claim 2,
wherein the metal oxide comprises indium, an element M (M is aluminum, gallium, yttrium, or tin), and zinc.

11. The semiconductor device according to claim 5,
wherein the metal oxide comprises indium, an element M (M is aluminum, gallium, yttrium, or tin), and zinc.

12. The semiconductor device according to claim 6,
wherein the metal oxide comprises indium, an element M (M is aluminum, gallium, yttrium, or tin), and zinc.
